(19) United States
(12) Patent Application Publication
(10) Pub. No.: US 2024/0239817 A1
(43) Pub. Date: Jul. 18, 2024

(54) METAL OXIDE THIN FILM PRECURSOR, METHOD OF FABRICATING METAL THIN FILM USING THE SAME, AND SEMICONDUCTOR DEVICE INCLUDING THE METAL OXIDE THIN FILM

(71) Applicant: UNIVERSITY-INDUSTRY COOPERATION GROUP OF KYUNG HEE UNIVERSITY, Yongin-si (KR)

(72) Inventors: Jongwook PARK, Seoul (KR); Woojin JEON, Yongin-si (KR); Sunwoo PARK, Gwangju-si (KR); Hayoon LEE, Incheon (KR); Sang Wook PARK, Paju-si (KR); Yoona CHOI, Seoul (KR); Yeong Jae HEO, Ansan-si (KR)

(21) Appl. No.: 18/524,155

(22) Filed: Nov. 30, 2023

(30) Foreign Application Priority Data
Dec. 23, 2022 (KR) 10-2022-0183395

(51) Int. Cl. C07F 7/00; C01G 25/02; C23C 16/40; C23C 16/455; H01L 21/02

(52) U.S. Cl. CPC C07F 7/00; C01G 25/02; C23C 16/405; C23C 16/45553; H01L 21/02189; H01L 21/0228; H01L 28/40

(57) ABSTRACT

Disclosed are a metal oxide thin film precursor represented by Chemical Formula 1, a method of fabricating a metal oxide thin film using the same, and a semiconductor device including the metal oxide thin film.

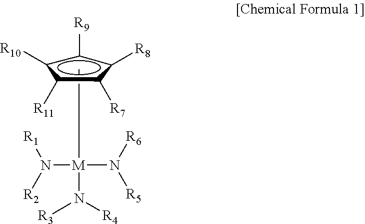

The definition of Chemical Formula 1 is as described in the detailed description.

### CROSS-REFERENCE TO RELATED APPLICATION

This application claims priority to and the benefit of Korean Patent Application No. 10-2022-0183395 filed in the Korean Intellectual Property Office on Dec. 23, 2022, the entire contents of which are incorporated herein by reference.

### BACKGROUND OF THE INVENTION

### (a) Field of the Invention

The present invention relates to a metal oxide thin film precursor, a method of fabricating metal thin film using the same, and a semiconductor device including the same.

### (b) Description of the Related Art

In the big data industry, one of the most important industries of the 4^{th} industrial revolution, as an amount of data to be processed is increased, and a demand for various electronic devices is increased, DRAM is being more necessary and important. In this regard, a market for DRAM has grown rapidly over the past few decades, and this growth has reached an unprecedented level in recent years. Since a capacitor mainly determines operating characteristics of a DRAM device, most of research on DRAM is focused on improving performance of DRAM capacitors. The DRAM capacitors have a MIM (Metal-Insulator-Metal) structure and require low leakage current density and high capacitance density for thorough operations (e.g.: reading, writing, and refreshing).

In order to solve this problem, research on high dielectric (high-k) materials with excellent insulation and a high dielectric constant is being actively conducted. Furthermore, as the semiconductor structure becomes more direct and refined, increasing is a demand for a precursor organometallic compound, which is a high dielectric material with high thermal stability and high volatility and is possibly liquid at room temperature, so that it may be applied to various processes (for example, an atomic layer deposition (ALD) method, a chemical vapor deposition (CVD) method, etc.) to secure excellent step coverage in fine patterns.

In order to increase capacitance of the DRAM capacitors, a dielectriclayer with a high dielectric constant is required. A method of increasing a dielectric constant without changing a dielectric layer material is to increase crystallinity of the dielectric layer material. This crystallinity is improved by increasing a deposition temperature. However, in the atomic layer deposition method (ALD process) of depositing the dielectric layer, since an upper limit of a process window of a process temperature is determined by a thermal decomposition temperature of a precursor, it is the most important factor to secure thermal stability of the precursor. In other words, a precursor having high thermal stability may be used to increase the temperature of the atomic layer deposition method (ALD process) and thus improve crystallinity, resultantly improving a dielectric constant of a dielectric layer and thereby increasing capacitance thereof.

However, the current performance of the dielectric layer (metal oxide thin film) for a semiconductor device, which exhibits capacitance at a predetermined level as well as minimizes a leakage current, does not meet the needs of the market. Accordingly, the present inventors have used a precursor with thermal stability to increase crystallinity of a dielectric layer and thereby increase a dielectric constant of the dielectric layer, ultimately developing a semiconductor device having low leakage current density and high capacitance density, specifically, a DRAM capacitor.

### SUMMARY OF THE INVENTION

An embodiment provides a metal oxide thin film precursor that has excellent thermal stability and can be stably used in a deposition process.

Another embodiment provides a method of forming a metal oxide thin film that is uniformly formed by depositing the metal oxide thin film precursor to secure excellent thin film properties, thin thickness, and sufficient step coverage.

Another embodiment provides a semiconductor device including a metal oxide thin film formed by the above method.

According to an embodiment, a metal oxide thin film precursor represented by Chemical Formula 1 is provided.

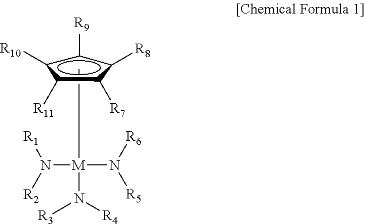

In Chemical Formula 1,
M is titanium (Ti), zirconium (Zr), or hafnium (Hf),
R¹ to R⁶ are each independently hydrogen, a halogen atom, a substituted or unsubstituted C1 to C6 alkyl group, a substituted or unsubstituted C2 to C6 alkenyl group, a substituted or unsubstituted C1 to C6 heteroalkyl group, or a substituted or unsubstituted silyl group,
R⁷ to R¹¹ are each independently hydrogen, a halogen atom, a substituted or unsubstituted C1 to C6 alkyl group, a substituted or unsubstituted C2 to C6 alkenyl group, a substituted or unsubstituted C1 to C6 heteroalkyl group, or a substituted or unsubstituted silyl group,
provided that, at least one of R¹ to R¹¹ necessarily includes a halogen atom,
at least one of R¹ to R⁶ may be linked to at least one of R⁷ to R¹¹ to form a fused ring,
R¹ and R² may be linked to each other to form a fused ring,
R³ and R⁴ may be linked to each other to form a fused ring,
R⁵ and R⁶ may be linked to each other to form a fused ring,
at least one of R¹ and R² and at least one of R³ and R⁴ may be linked to each other to form a fused ring,
at least one of R³ and R⁴ and at least one of R⁵ and R⁶ may be linked to each other to form a fused ring, and
at least one of R¹ and R² and at least one of R⁵ and R⁶ may be linked to each other to form a fused ring.
R¹ to R⁶ may each independently be a substituted or unsubstituted C1 to C6 alkyl group, a substituted or unsubstituted C1 to C6 heteroalkyl group, or a substituted or unsubstituted silyl group.

At least one of R⁷ to R¹¹ may be necessarily a halogen atom.

Any one of R⁷ to R¹¹ may be a halogen atom, and all others may be hydrogen.

Any one of R⁷ to R¹¹ may be a halogen atom, and the others may be a substituted or unsubstituted C1 to C6 alkyl group, a substituted or unsubstituted C1 to C6 heteroalkyl group, or a substituted or unsubstituted silyl group.

At least two of R⁷ to R¹¹ may be necessarily halogen atoms.

At least three of R⁷ to R¹¹ may be necessarily halogen atoms.

At least four of R⁷ to R¹¹ may be necessarily halogen atoms.

All of R⁷ to R¹¹ may be halogen atoms.

R⁶ and R⁸ may be linked to each other to form a fused ring.

R³ and R⁴ may be linked to each other to form a fused ring.

R⁴ and R⁵ may be linked to each other to form a fused ring.

Chemical Formula 1 may be represented by Chemical Formulas 2-1 to 2-16.

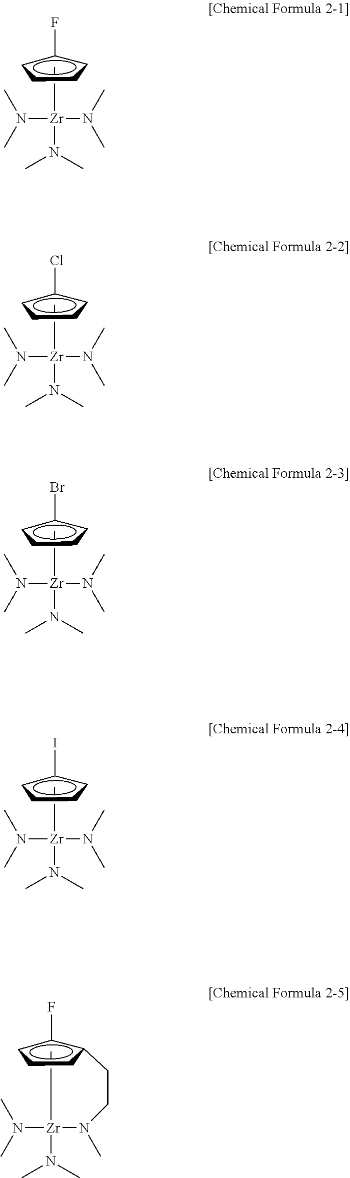

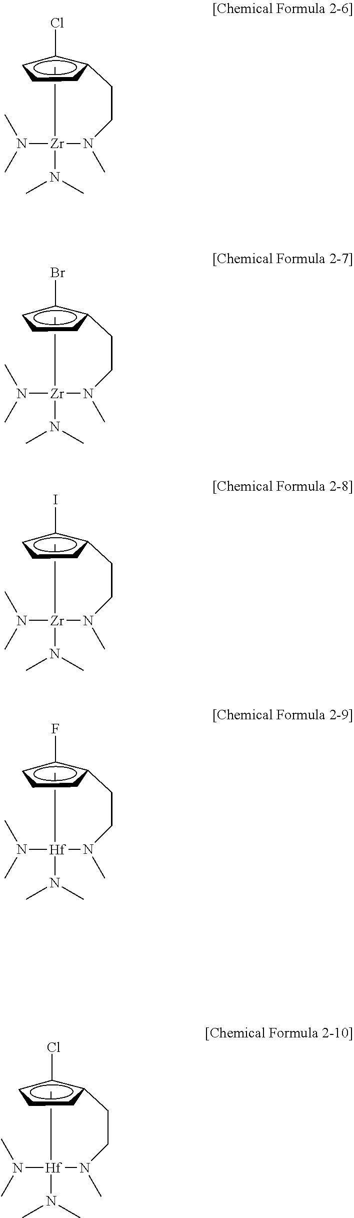

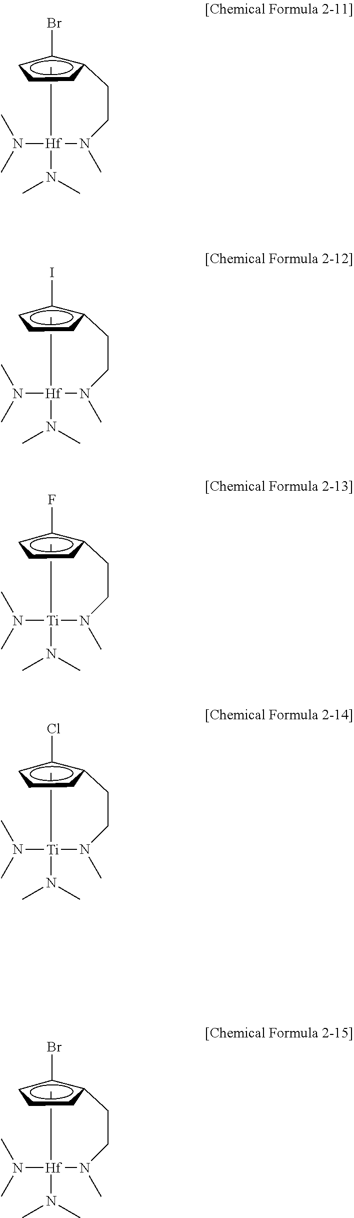

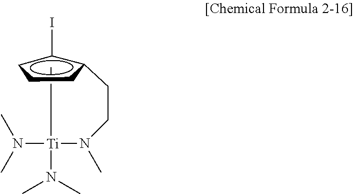

Chemical Formula 1 may be represented by any one of Chemical Formulas 3-1 to 3-12.

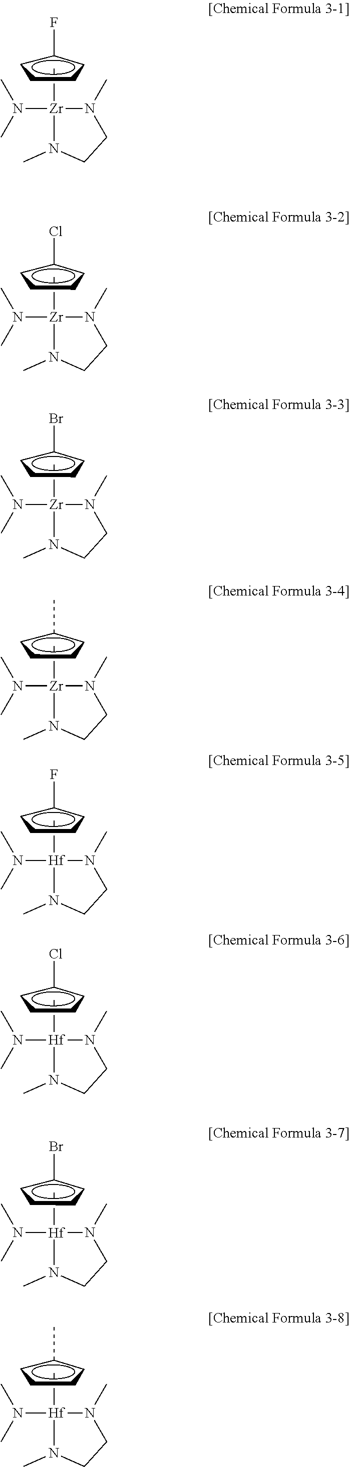

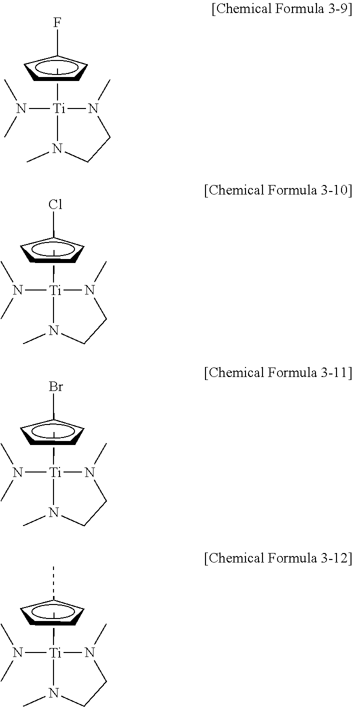

Chemical Formula 1 may be represented by any one of Chemical Formulas 4-1 to 4-12.

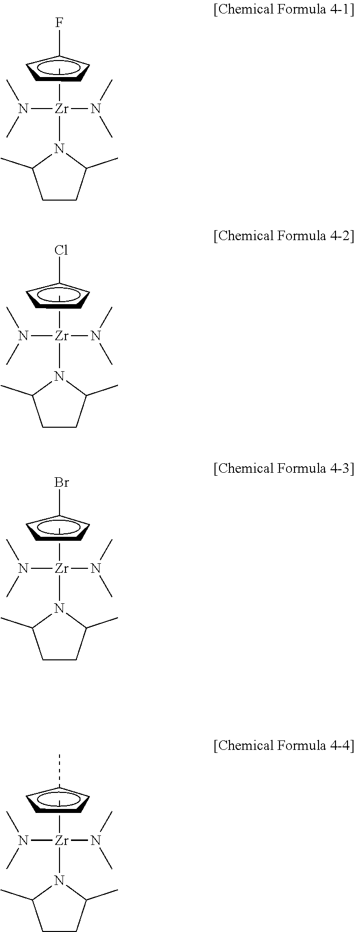

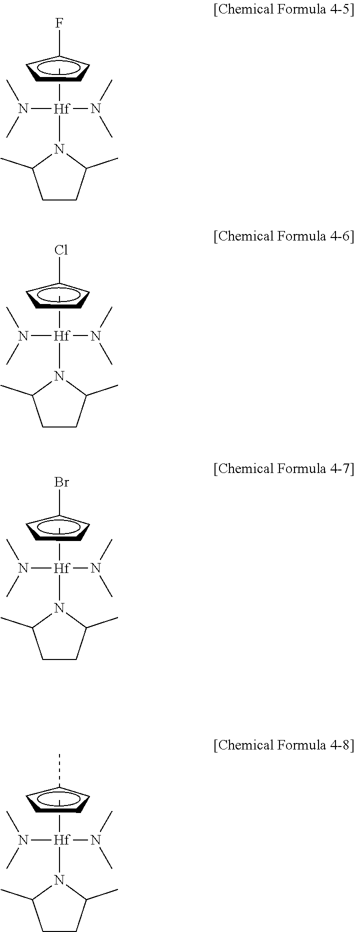

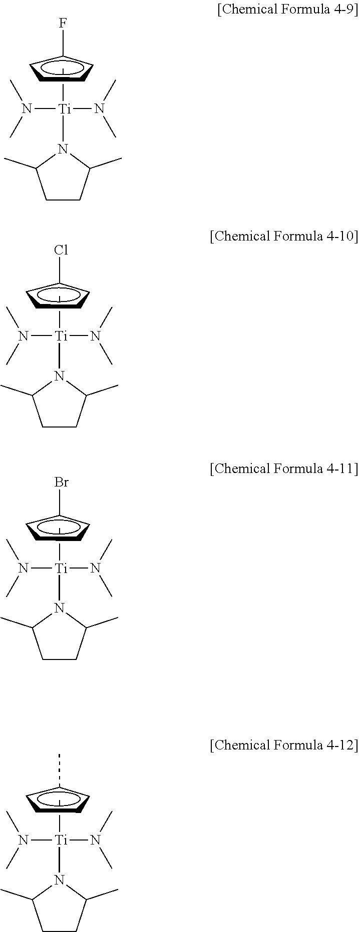

Chemical Formula 1 may be represented by any one of Chemical Formulas 5-1 to 5-12.

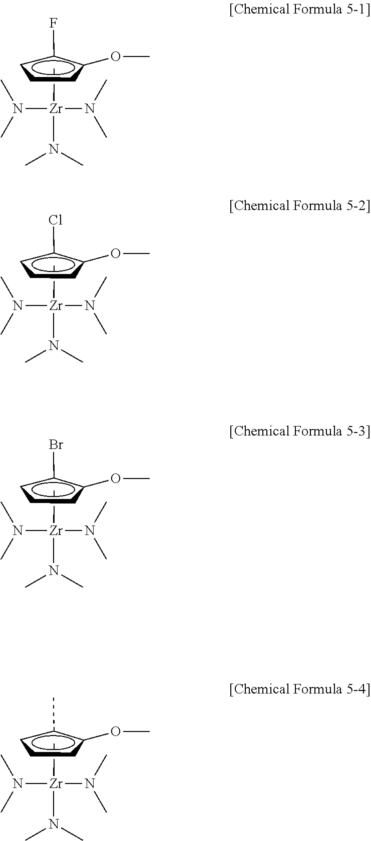

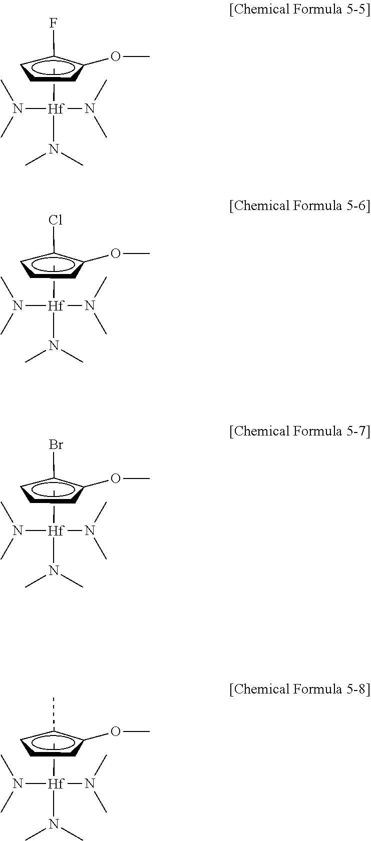

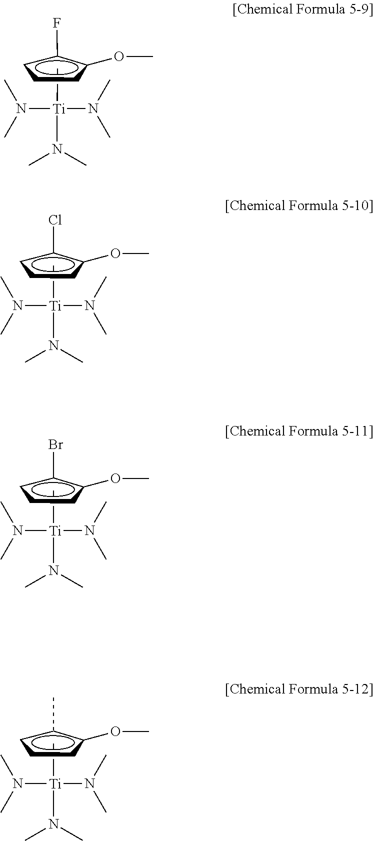

Chemical Formula 1 may be represented by any one of Chemical Formulas 6-1 to 6-12.

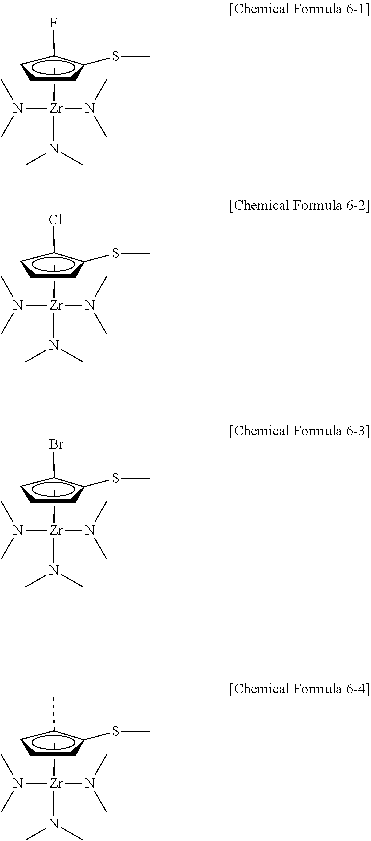

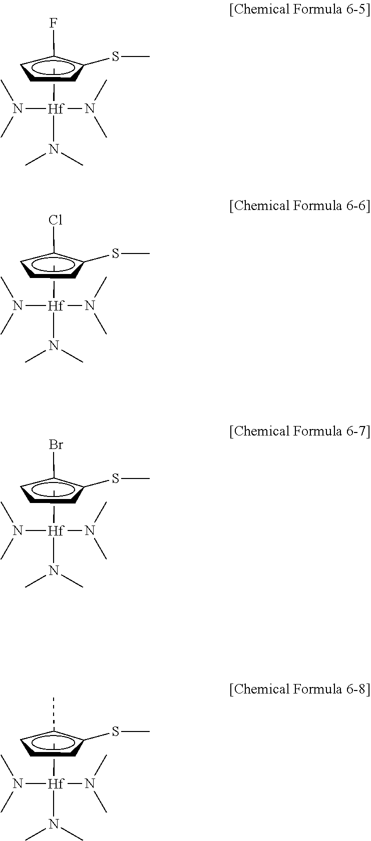

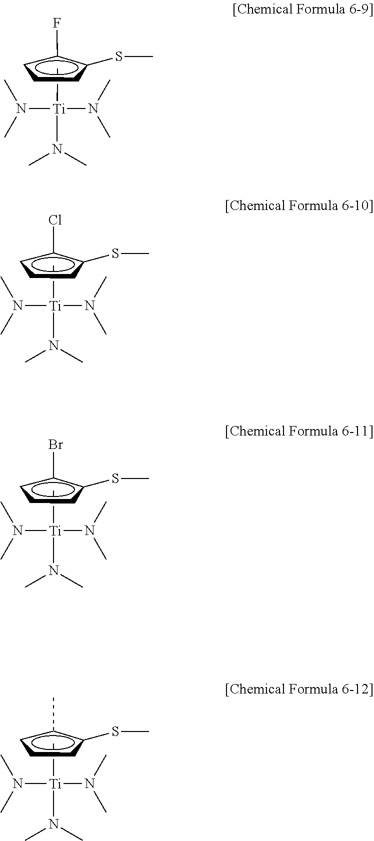

Chemical Formula 1 may be represented by any one of Chemical Formulas 7-1 to 7-12.

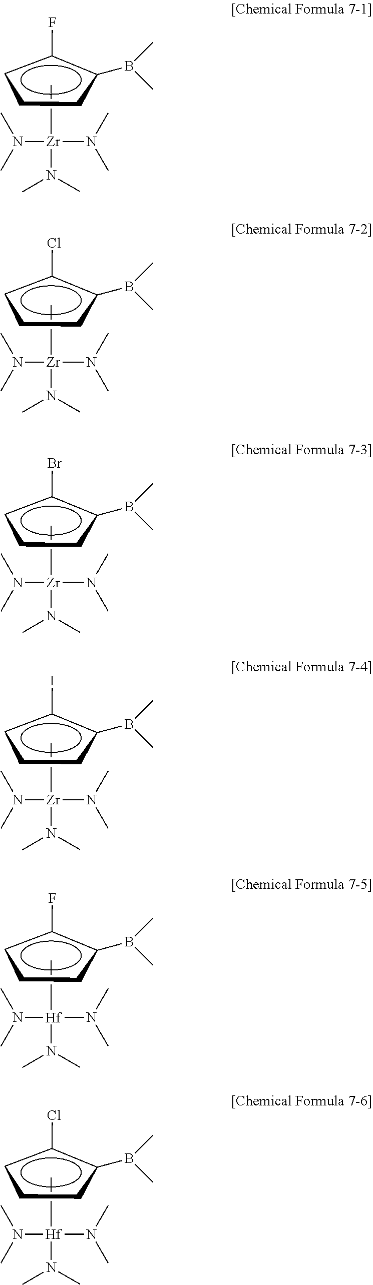

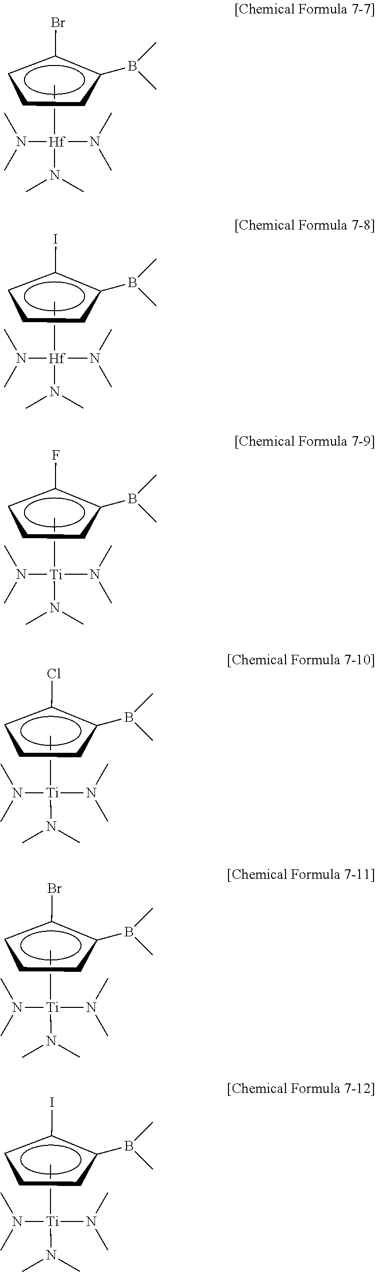

Chemical Formula 1 may be represented by any one of Chemical Formulas 8-1 to 8-12.

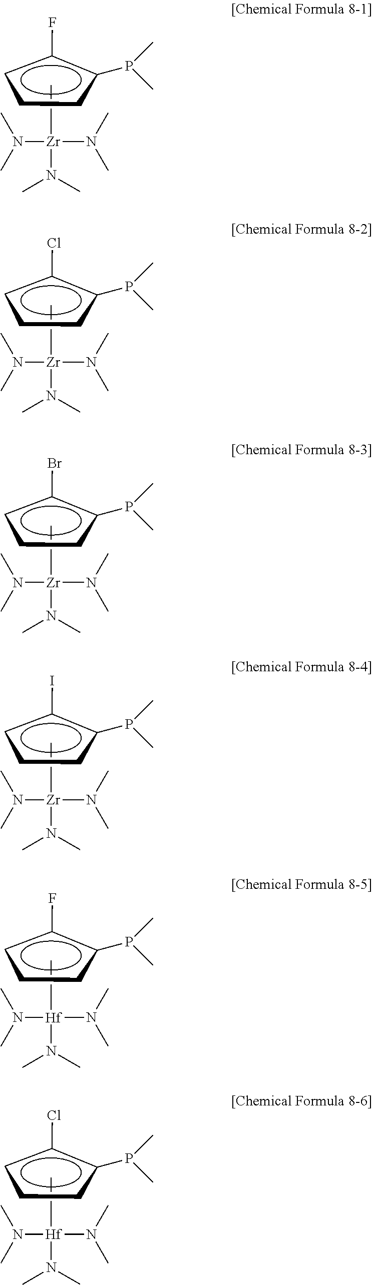

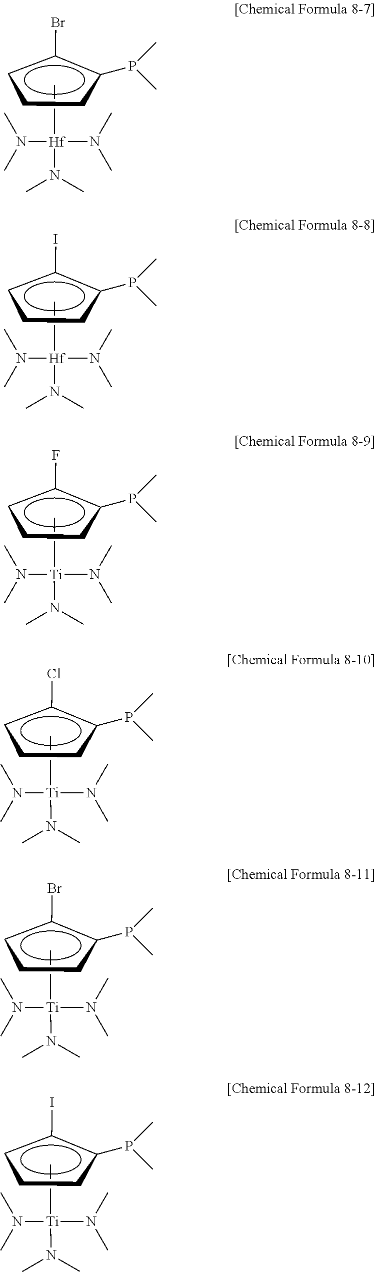

Chemical Formula 1 may be represented by any one of Chemical Formulas 9-1 to 9-12.

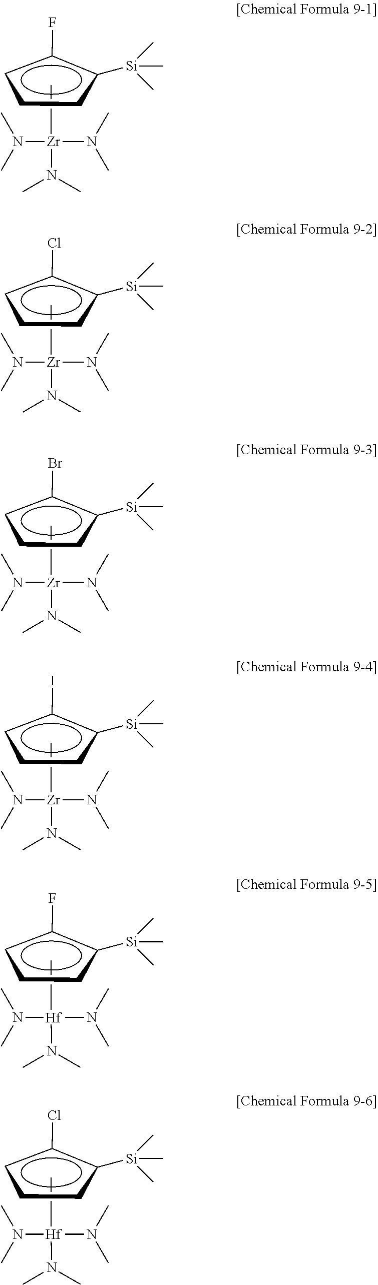

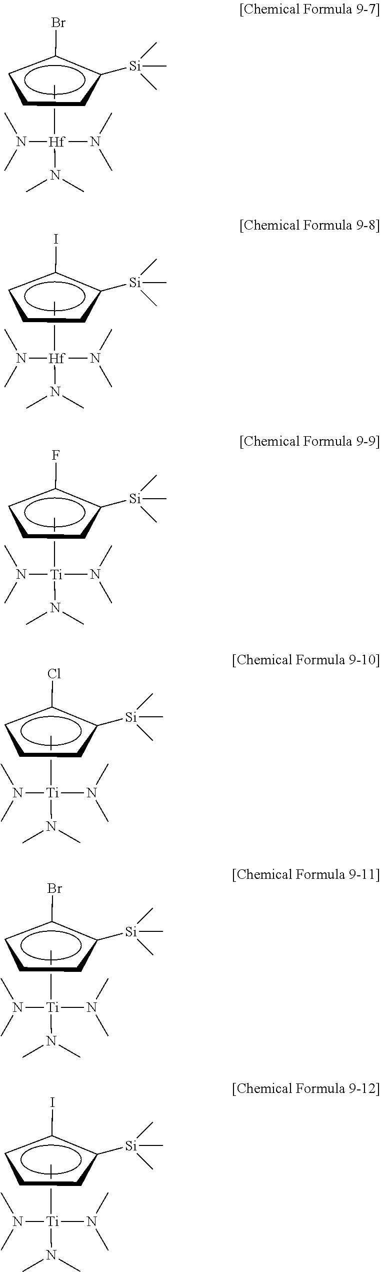

Chemical Formula 1 may be represented by any one of Chemical Formulas 10-1 to 10-12.

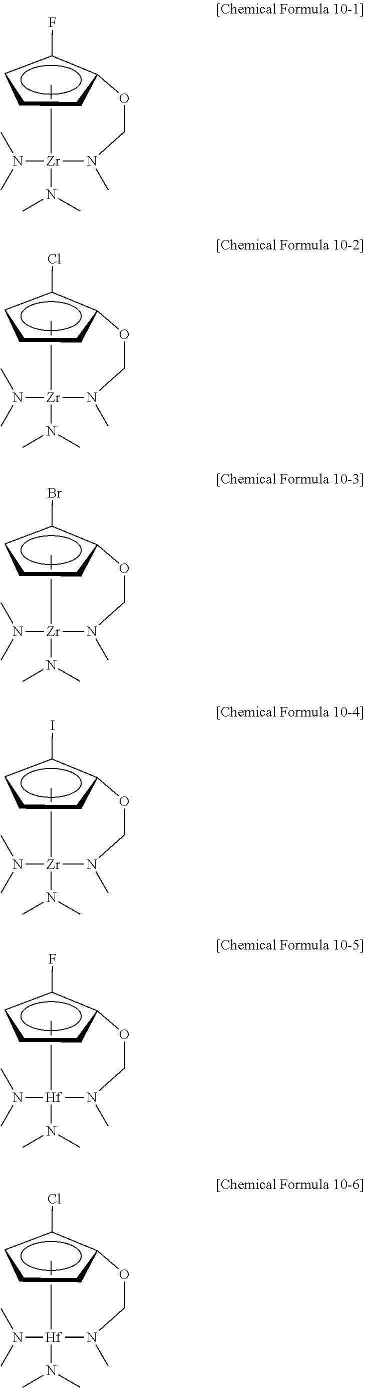

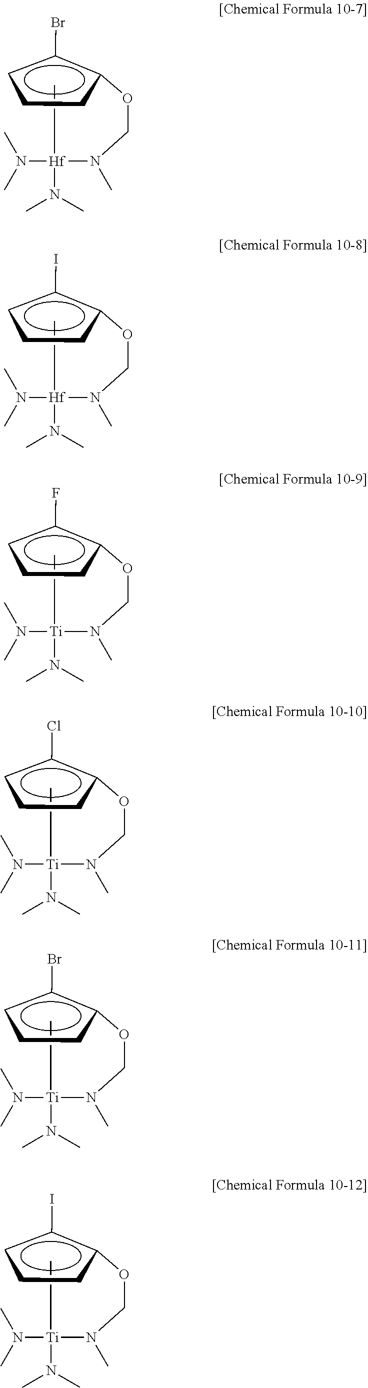

Chemical Formula 1 may be represented by any one of Chemical Formulas 11-1 to 11-12.

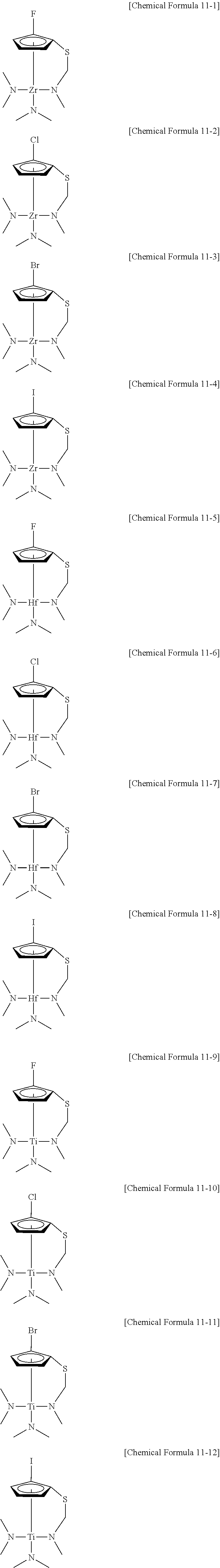

Chemical Formula 1 may be represented by any one of Chemical Formulas 12-1 to 12-12.

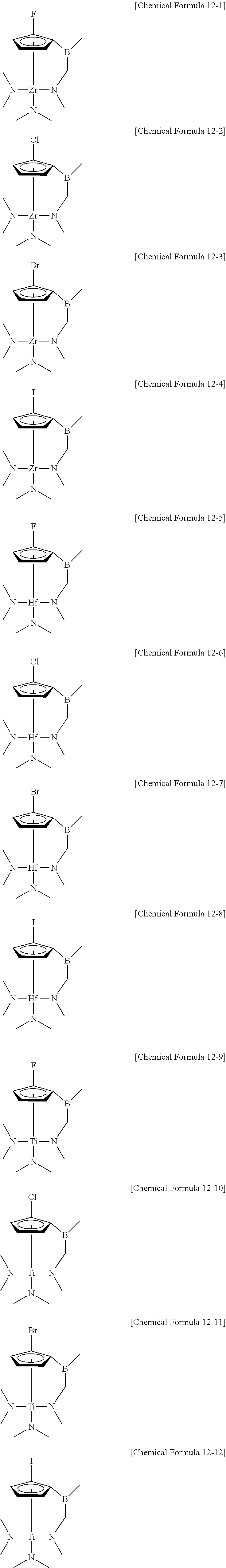

Chemical Formula 1 may be represented by any one of Chemical Formulas 13-1 to 13-12.

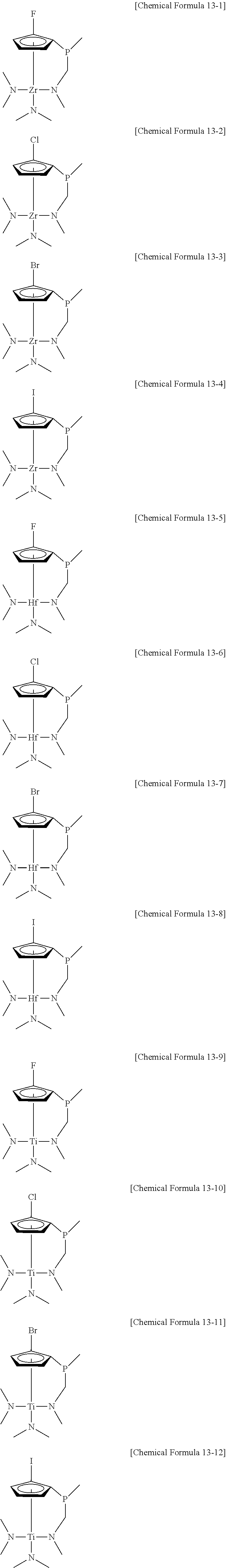

Chemical Formula 1 may be represented by any one of Chemical Formulas 14-1 to 14-12.

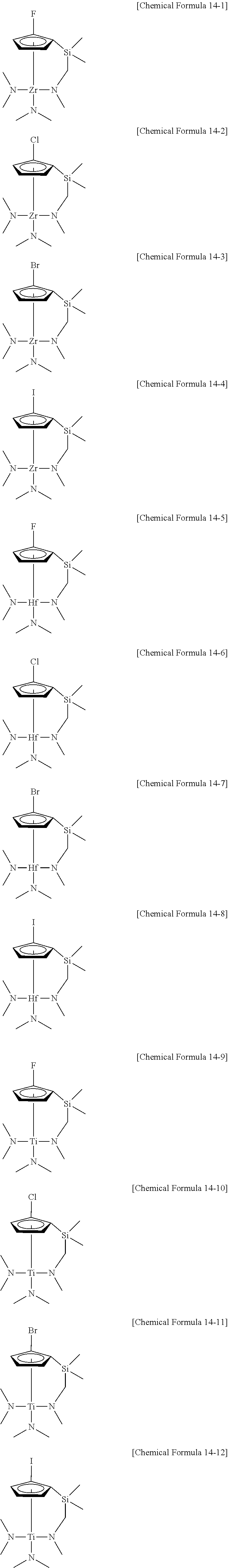

Chemical Formula 1 may be represented by any one of Chemical Formulas 15-1 to 15-12.

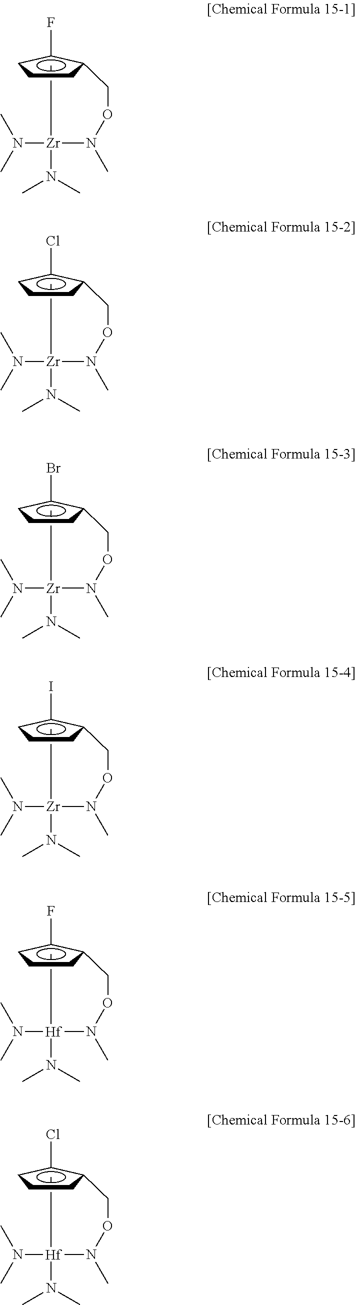

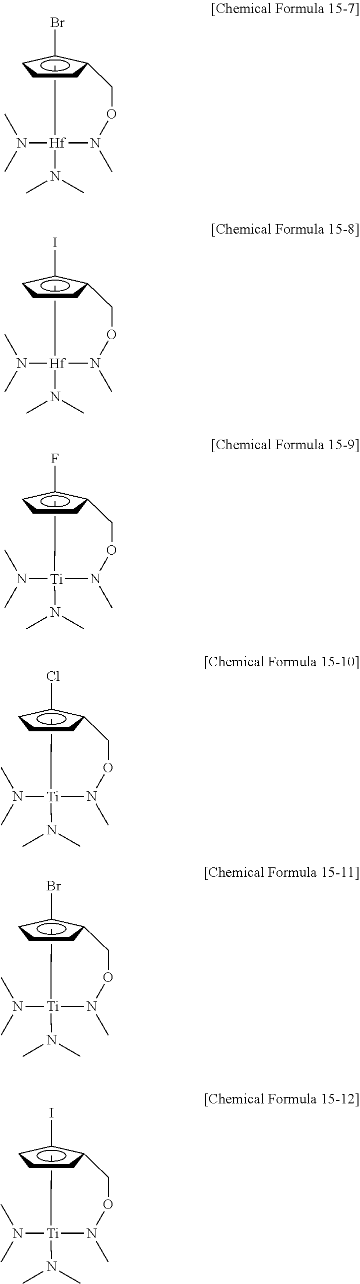

Chemical Formula 1 may be represented by any one of Chemical Formulas 16-1 to 16-12.

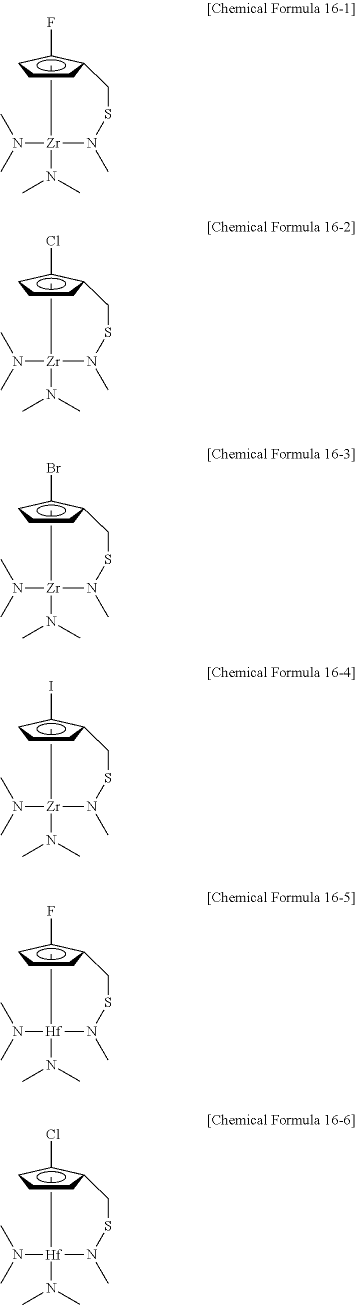

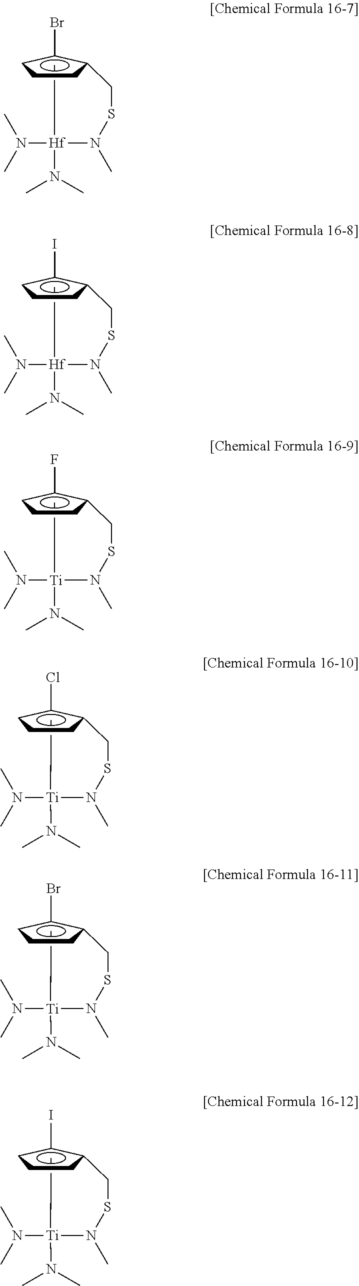

Chemical Formula 1 may be represented by any one of Chemical Formulas 17-1 to 17-12.

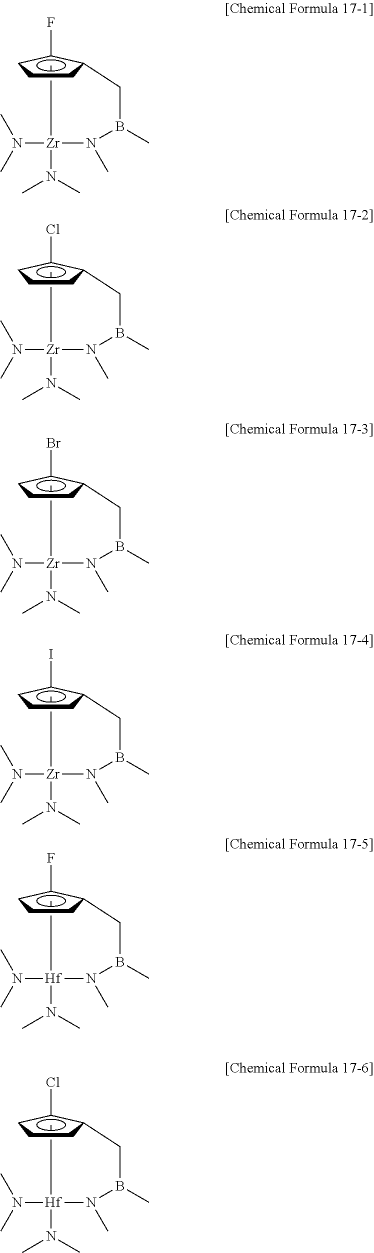

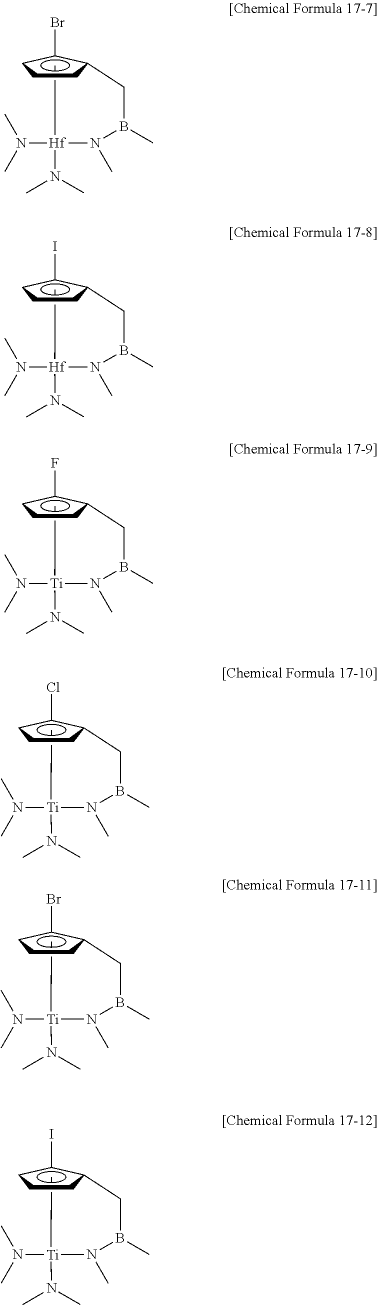

Chemical Formula 1 may be represented by any one of Chemical Formulas 18-1 to 18-12.

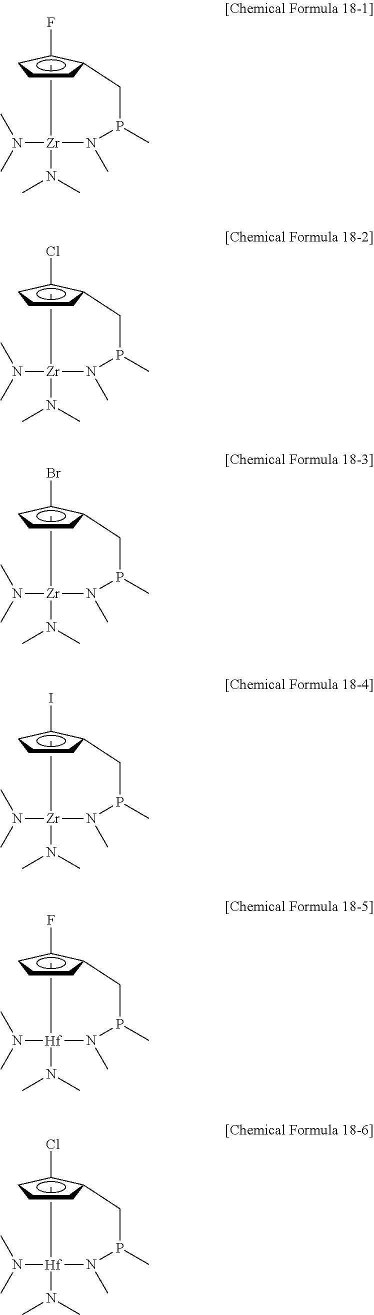

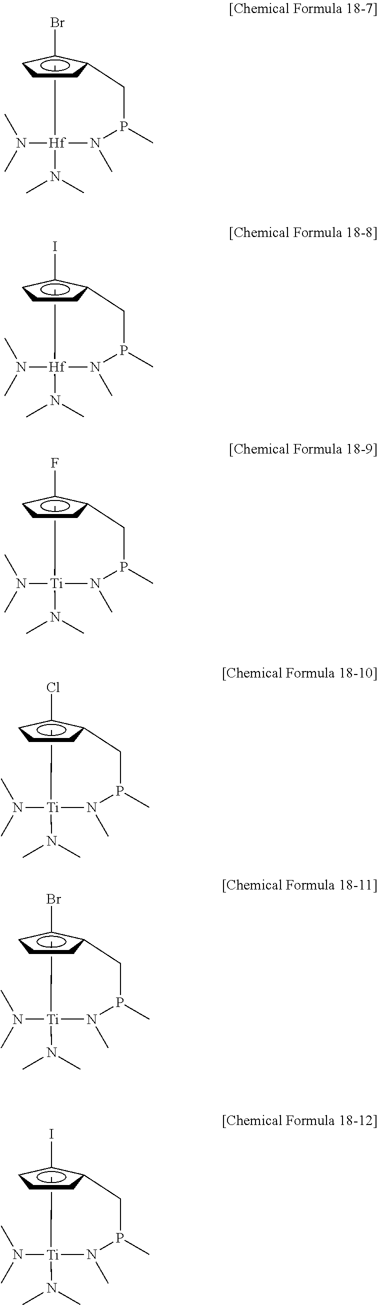

Chemical Formula 1 may be represented by any one of Chemical Formulas 19-1 to 19-12.

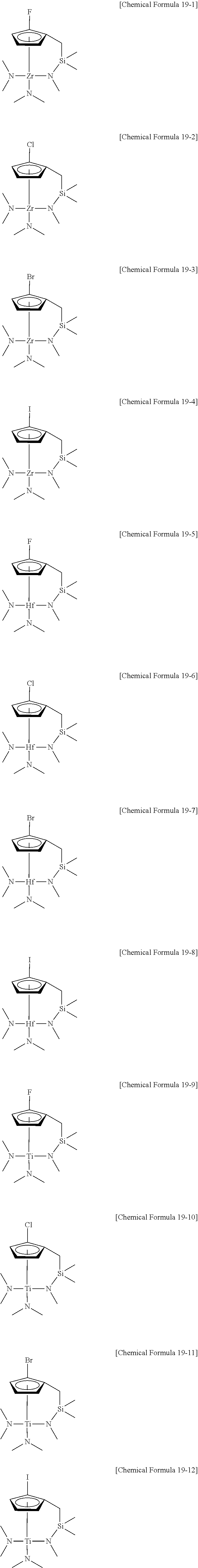

Another embodiment includes a method of forming a metal oxide thin film which includes a first step of supplying the metal oxide thin film precursor onto a substrate and adsorbing the metal oxide thin film precursor onto the surface of the substrate; a second step of supplying at least one of an oxygen-containing gas, a nitrogen-containing gas, and plasma to react with the metal oxide thin film precursor to form a metal oxide thin film on the substrate, and a third step of sequentially repeating the first step and the second step.

The oxygen-containing gas may include aqueous vapor (H₂O), oxygen (O₂), ozone (O₃), hydrogen peroxide (H₂O₂), nitrous oxide (N₂O), or a combination thereof.

The nitrogen-containing gas may include nitrogen (N₂), ammonia (NH₃), hydrazine (N₂H₄), nitrous oxide (N₂O), or a combination thereof.

The method of forming a metal oxide thin film may include an atomic layer deposition (ALD) or a metal organic chemical vapor deposition (MOCVD).

Another embodiment provides a semiconductor device including a metal oxide thin film formed by the method of forming a metal oxide thin film.

The metal oxide thin film precursor according to an embodiment not only exists in a liquid state at room temperature, making it easy to store and handle, but also has high volatility, and thus the deposition rate is fast and easy, and it has excellent thermal stability and excellent growth of highly crystalline thin films, resulting in high reactivity, and a thin film manufactured using this as a precursor have high purity and excellent physical and electrical properties.

Therefore, a metal oxide thin film formed using the metal oxide thin film precursor according to an embodiment can improve leakage current characteristics, and a capacitor metal oxide thin film (dielectric film) including this may have improved capacitance.

### BRIEF DESCRIPTION OF THE DRAWINGS

FIG. 1 is a graph showing the change in thickness of the metal oxide thin film (ZrO₂) as the step of forming a metal oxide thin film (ZrO₂) is repeated using the metal oxide thin film precursors according to Example 1 and Comparative Example 1, respectively.

FIG. 2 is a graph showing the crystallinity of a metal oxide thin film (ZrO₂) formed using the metal oxide thin film precursors according to Example 1 and Comparative Example 1, respectively.

FIG. 3 is an X-ray photoelectron spectroscopy (XPS) graph of a metal oxide thin film (ZrO₂) formed using the metal oxide thin film precursors according to Example 1 and Comparative Example 1, respectively.

FIG. 4 is a graph showing the composition of a metal oxide thin film (ZrO₂) formed using the metal oxide thin film precursor according to Comparative Example 1.

FIG. 5 is a graph showing the composition of a metal oxide thin film (ZrO₂) formed using the metal oxide thin film precursor according to Example 1.

FIG. 6 is a schematic diagram showing the layered structure of a DRAM capacitor composed of a MIM (Metal-Insulator-Metal) structure.

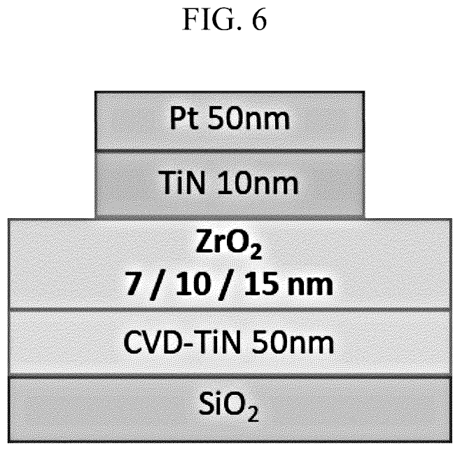

FIG. 7 is a graph showing the dielectric constant and leakage current density of metal oxide thin films (ZrO₂) formed using the metal oxide thin film precursors according to Example 1 and Comparative Example 1, respectively.

### DETAILED DESCRIPTION OF THE EMBODIMENTS

Hereinafter, embodiments of the present invention are described in detail. However, these embodiments are exemplary, the present invention is not limited thereto and the present invention is defined by the scope of claims.

As used herein, when a definition is not otherwise provided, “substituted” refers to replacement of at least one hydrogen of a substituent or a compound by deuterium, NH₂, a C1 to C4 amine group, a nitro group, a C1 to C4 silyl group, a C1 to C4 alkyl group, a C1 to C4 alkylsilyl group, a C1 to C4 alkoxy group, a fluoro group, a C1 to C4 trifluoroalkyl group, or a cyano group.

As used herein, a halogen atom means one or more selected from fluorine (F), chlorine (Cl), bromine (Br), and iodine (I).

As used herein, when a definition is not otherwise provided, “alkyl group” means an aliphatic hydrocarbon group. The alkyl group may be “a saturated alkyl group” without any double bond or triple bond.

The alkyl group may be a C1 to C30 alkyl group. More specifically, the alkyl group may be a C1 to C20 alkyl group, a C1 to C10 alkyl group, a C1 to C6 alkyl group, or a C1 to C4 alkyl group. For example, a C1 to C4 alkyl group may have one to four carbon atoms in the alkyl chain, and may be selected from methyl, ethyl, propyl, iso-propyl, n-butyl, iso-butyl, sec-butyl, and t-butyl.

Specific examples of the alkyl group may be a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, and the like.

In this specification, “heteroalkyl group” refers to a heterogroup having an alkyl group as a substituent, and may include an alkoxy group, etc. For example, “heteroalkyl group” may be represented by *—X¹R (X¹ is an oxygen atom or a sulfur atom and R is a substituted or unsubstituted alkyl group) or *—X²R′R″ (X² is a boron atom, a nitrogen atom, or a phosphorus atom, R′ and R″ are each independently a hydrogen atom or a substituted or unsubstituted alkyl group).

The terms used in the present specification are used for describing exemplary embodiments and are not intended to limit the present disclosure. In the present specification, the singular form also includes the plural form unless specifically stated otherwise in the description. As used in the specification, “comprises” and/or “comprising” mean that the mentioned components, steps, operations and/or elements do not exclude the presence or addition of one or more other components, steps, operations and/or elements. Additionally, in this specification, when a film is referred to as being on another film or substrate, it means that it can be formed directly on the other film or substrate, or a third film can be interposed between them.

Hereinafter, a metal oxide thin film precursor according to an embodiment will be described.

A metal oxide thin film precursor according to an embodiment is represented by Chemical Formula 1.

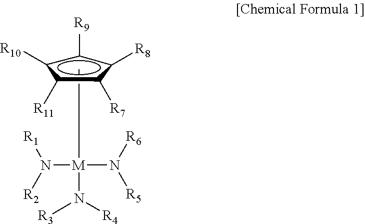

In Chemical Formula 1,
M is titanium (Ti), zirconium (Zr), or hafnium (Hf),
R¹ to R⁶ are each independently hydrogen, a halogen atom, a substituted or unsubstituted C1 to C6 alkyl group, a substituted or unsubstituted C2 to C6 alkenyl group, a substituted or unsubstituted C1 to C6 heteroalkyl group, or a substituted or unsubstituted silyl group,
R⁷ to R¹¹ are each independently hydrogen, a halogen atom, a substituted or unsubstituted C1 to C6 alkyl group, a substituted or unsubstituted C2 to C6 alkenyl group, a substituted or unsubstituted C1 to C6 heteroalkyl group, or a substituted or unsubstituted silyl group, provided that, at least one of R¹ to R¹¹ necessarily includes a halogen atom.

For example, at least one of R¹ to R⁶ may be linked to at least one of R⁷ to R¹¹ to form a fused ring.

For example, R¹ and R² may be linked to each other to form a fused ring.

For example, R² and R³ may be linked to each other to form a fused ring.

For example, R³ and R⁴ may be linked to each other to form a fused ring.

For example, R⁴ and R⁵ may be linked to each other to form a fused ring.

For example, R⁵ and R⁶ may be linked to each other to form a fused ring.

For example, at least one of R¹ and R² and at least one of R³ and R⁴ may be linked to each other to form a fused ring.

For example, at least one of R³ and R⁴ and at least one of R⁵ and R⁶ may be linked to each other to form a fused ring,

For example, at least one of R¹ and R² and at least one of R⁵ and R⁶ may be linked to each other to form a fused ring.

The present inventors have developed a stable deuterium-containing single organometallic precursor compound (metal oxide thin film precursor) which secures excellent thin film properties, thin thickness, and sufficient step coverage by using metal organic chemical vapor deposition (MOCVD) and/or atomic layer deposition (ALD), and are highly volatile, exist in a liquid state at room temperature, and are thermally stable. Furthermore, a thin film deposition method (method of forming a metal oxide thin film) using the organometallic precursor compound to form a metal oxide thin film through metal organic chemical vapor deposition (MOCVD) or atomic layer deposition (ALD) has been completed.

The metal oxide thin film precursor represented by Chemical Formula 1 includes a cyclopentadienyl group, which is an aromatic ring compound, thereby strengthening a bond between the metal and amine groups and making it stable. As a result, the metal oxide thin film precursor according to an embodiment may have stronger thermal stability and increase the thermal decomposition temperature compared to a conventional metal precursor containing only amine groups and not an aromatic ring compound.

In addition, the metal oxide thin film precursor represented by Chemical Formula 1 can exhibit high vapor pressure because the central metal atom is bonded to three amine groups that can cause high vapor pressure. In addition, the metal oxide thin film precursor represented by Chemical Formula 1 does not form corrosive products such as HCl as a by-product during deposition, thereby preventing corrosion of the device.

Furthermore, in the metal oxide thin film precursor represented by Chemical Formula 1, at least one of the five carbons constituting the cyclopentadienyl group is necessarily substituted with a halogen atom (or at least one of the substituents substituted for the amine group contains a halogen atom), an electron donor effect of the compound is strengthened, and through this, the characteristics of the electrically negative cyclopentadiene are improved, thereby strengthening the bonding force with the central metal, and significantly increasing the thermal stability of the metal oxide thin film precursor according to an embodiment, resulting in a decrease in leakage current. This increases the thermal decomposition temperature of the metal oxide thin film precursor in the process described later and widens the process temperature process window, allowing the process temperature to be set high. It also affects the crystallinity of the metal oxide thin film and the formation of a crystalline phase with a high dielectric constant, resulting in an increase in the dielectric constant of the metal oxide thin film (dielectric film). This increase in dielectric constant and decrease in leakage current ultimately increases capacitance, leading to improved capacitor performance.

In particular, in Chemical Formula 1, if at least one of R⁷ to R¹¹ necessarily includes a halogen atom, the electrically negative characteristics of cyclopentadiene can be greatly enhanced compared to materials substituted with hydrogen and thus the thermal stability of the compound represented by Chemical Formula 1 can be greatly increased. In fact, the cyclopentadienyl tris(dimethylamino) zirconium material substituted with a halogen atom has a much higher electronegativity than the material substituted with hydrogen. In light of these characteristics, materials substituted with halogen atoms produce TiO₂, ZrO₂, and HfO₂ at relatively high temperatures compared to materials substituted with hydrogen, and since the crystallinity of TiO₂, ZrO₂, and HfO₂ produced at high temperatures is due to the ease with which the crystals of the material find their original positions, the crystallinity of TiO₂, ZrO₂, and HfO₂ produced at high temperatures increases, and this increased crystallinity induce increases of the dielectric constant. Ultimately, using the metal oxide thin film precursor according to an embodiment can produce high capacitance.

For example, at least two, for example, three or more, for example, four or more of R⁷ to R¹¹ may be halogen atoms. When the halogen atom increases, crystallization into a tetragonal phase with a high dielectric constant among the metal oxide thin film crystal phases formed using the metal oxide thin film precursor represented by Chemical Formula 1 can occur more easily, resulting in providing a capacitor with increased electrostatic capacity.

For example, R⁷ to R¹¹ may all be halogen atoms. In this case, the thermal stability of the metal oxide thin film precursor represented by Chemical Formula 1 may be very excellent, and this may make it possible to provide a capacitor with increased electrostatic capacity.

For example, R¹ to R⁶ may each independently be a substituted or unsubstituted C1 to C6 alkyl group, a substituted or unsubstituted C1 to C6 heteroalkyl group, or a substituted or unsubstituted silyl group.

For example, R⁶ and R⁸ may be linked to each other to form a fused ring.

For example, R³ and R⁴ may be linked to each other to form a fused ring.

For example, R⁴ and R⁵ may be linked to each other to form a fused ring.

For example, any one of R⁷ to R¹¹ may be a halogen atom. In this case, all of R⁷ to R¹¹ except for the halogen atom may be hydrogen atoms.

For example, any one of R⁷ to R¹¹ may be a halogen atom. In this case, any one of R⁷ to R¹¹ except the halogen atom may be a substituted or unsubstituted C1 to C6 alkyl group, a substituted or unsubstituted C1 to C6 heteroalkyl group, or a substituted or unsubstituted silyl group.

For example, M may be Hf, in which case the process speed can be further increased when applied to atomic layer deposition.

For example, the metal oxide thin film precursor represented by Chemical Formula 1 may be represented by any one of Chemical Formulas 2-1 to 2-16, but is not necessarily limited thereto.

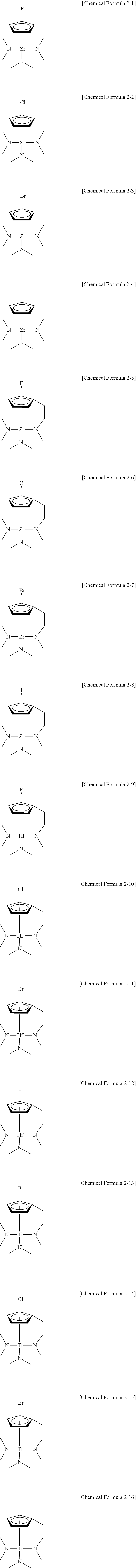

Chemical Formula 1 may be represented by any one of Chemical Formulas 3-1 to 3-12.

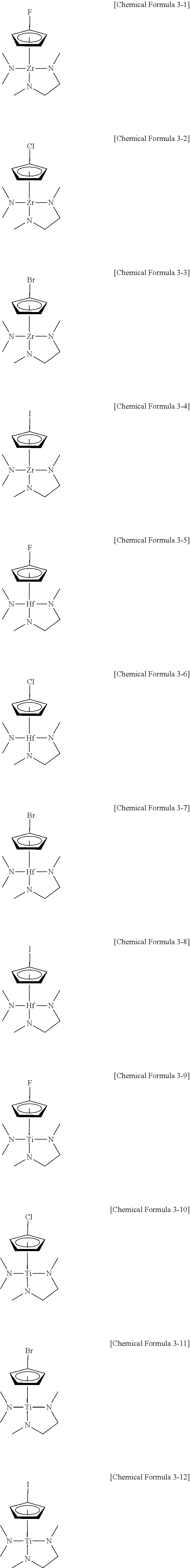

Chemical Formula 1 may be represented by any one of Chemical Formulas 4-1 to 4-12, but is not necessarily limited thereto.

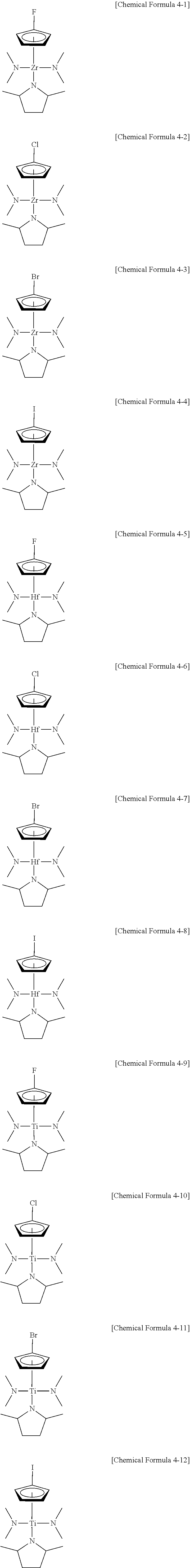

Chemical Formula 1 may be represented by any one of Chemical Formulas to 5-1 to 5-12, but is not necessarily limited thereto.

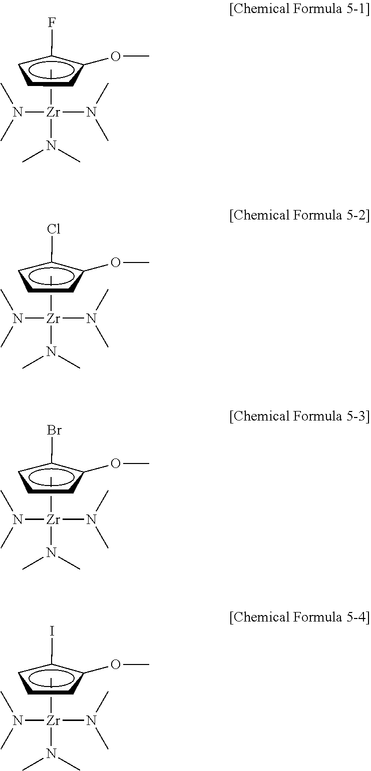

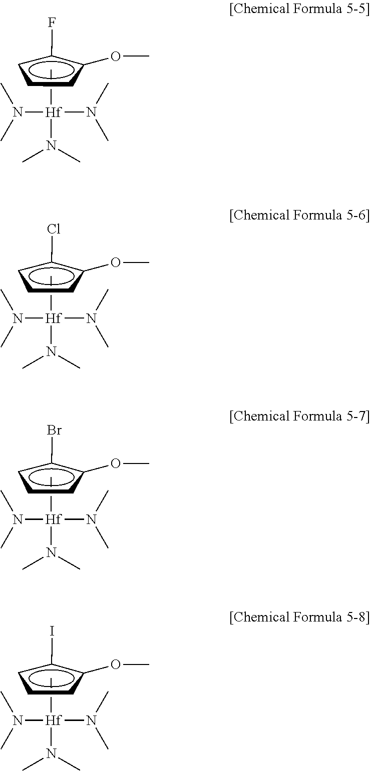

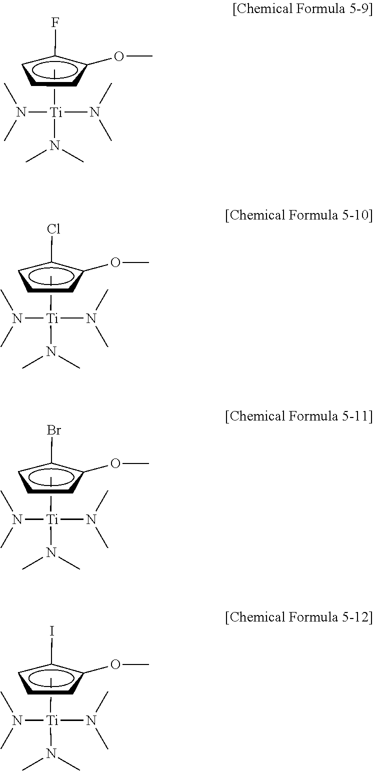

Chemical Formula 1 may be represented by any one of Chemical Formulas 6-1 to 6-12, but is not necessarily limited thereto.

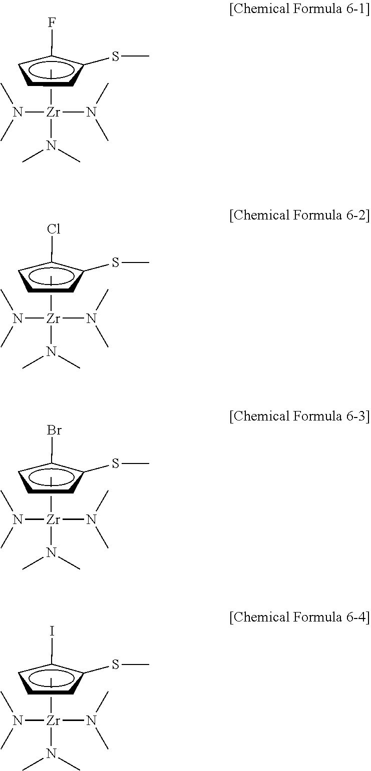

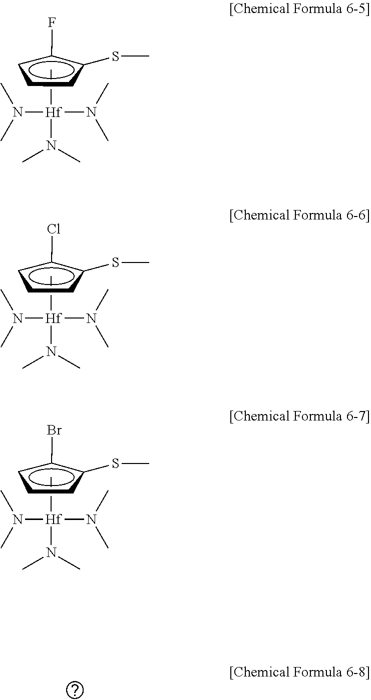

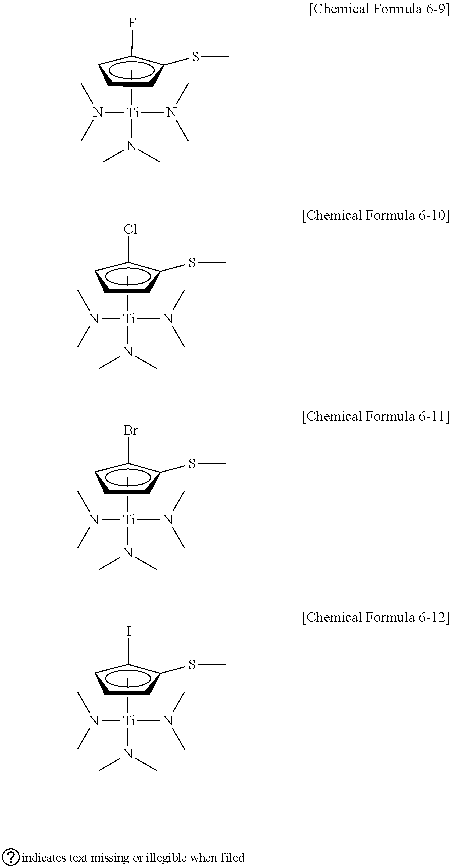

Chemical Formula 1 may be represented by any one of Chemical Formulas 7-1 to 7-12, but is not necessarily limited thereto.

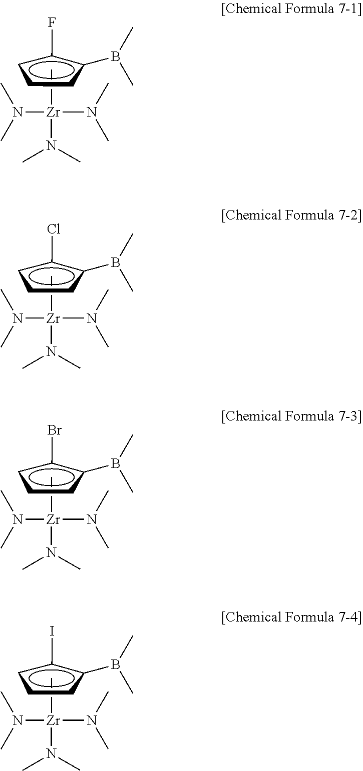

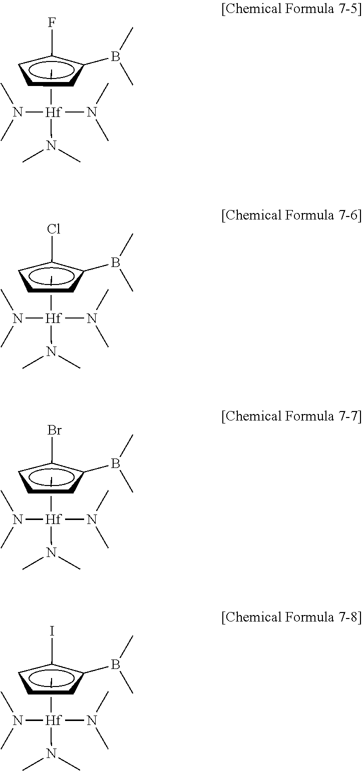

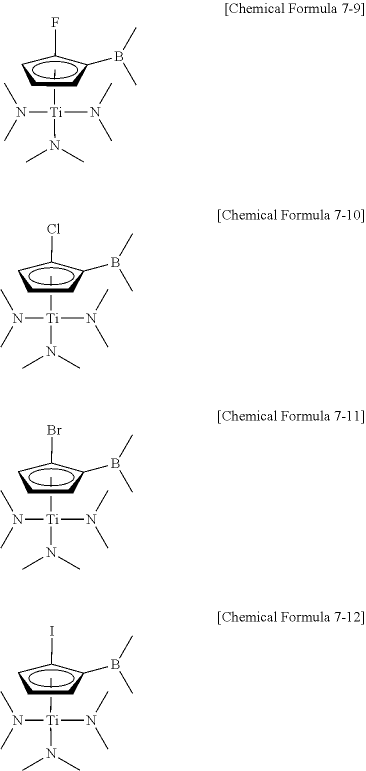

Chemical Formula 1 may be represented by any one of Chemical Formulas 8-1 to 8-12, but is not necessarily limited thereto.

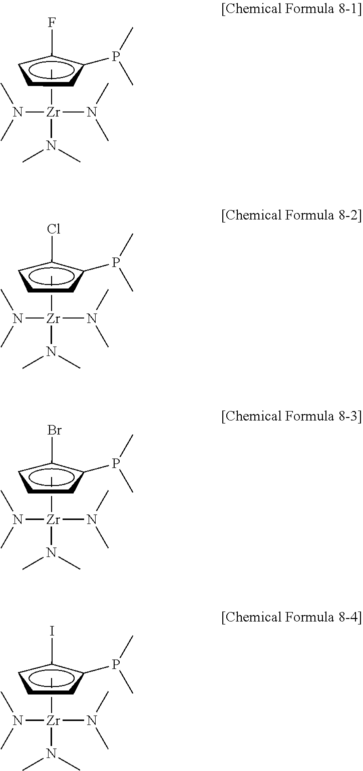

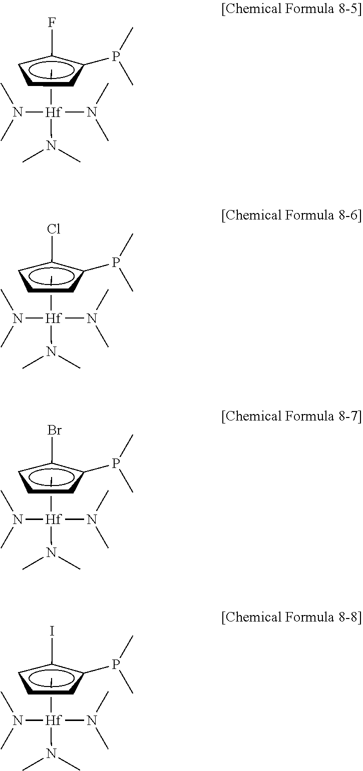

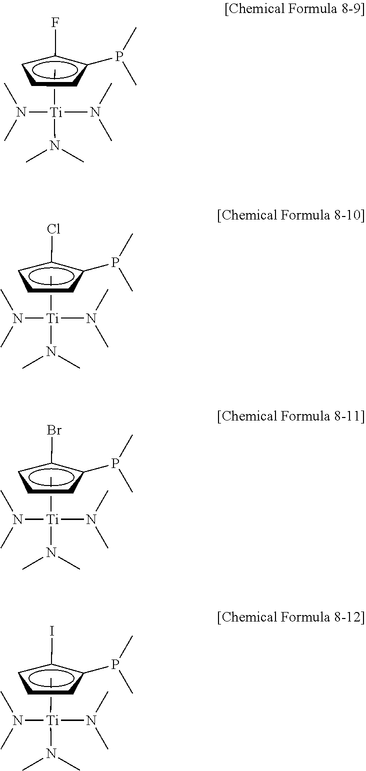

Chemical Formula 1 may be represented by any one of Chemical Formulas 9-1 to 9-12, but is not necessarily limited thereto.

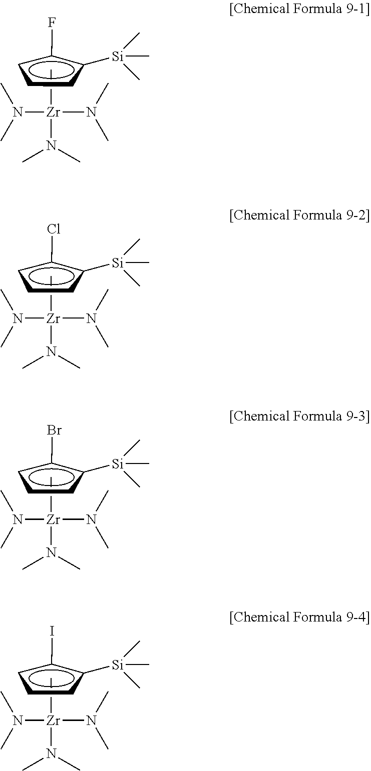

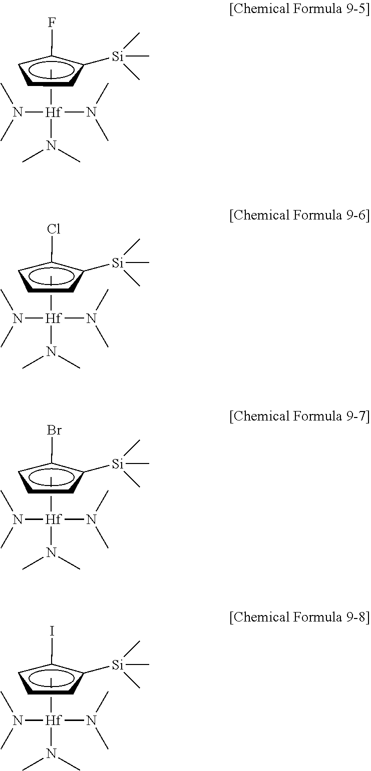

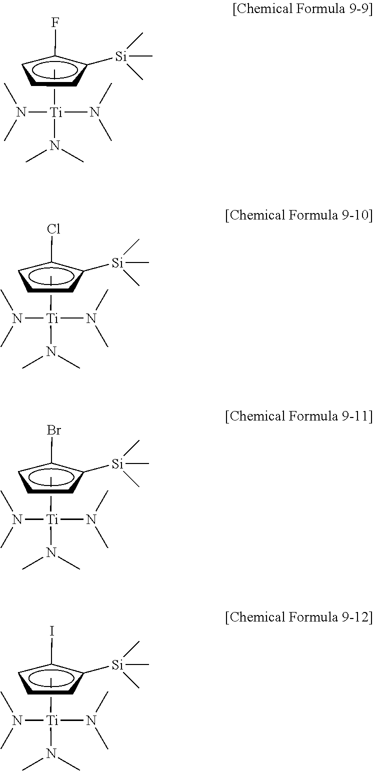

Chemical Formula 1 may be represented by any one of Chemical Formulas 10-1 to 10-12, but is not necessarily limited thereto.

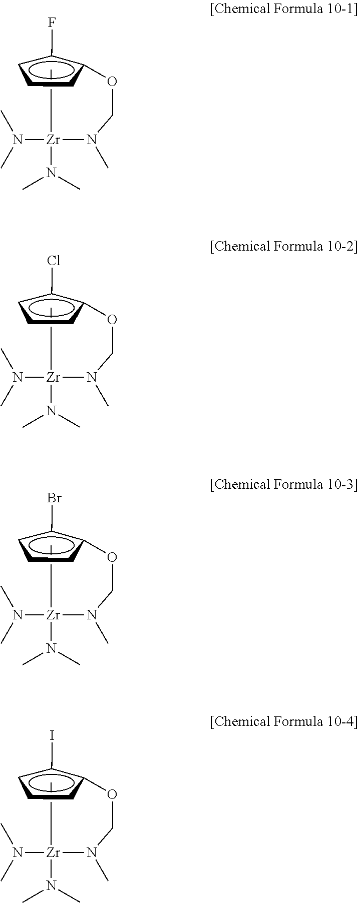

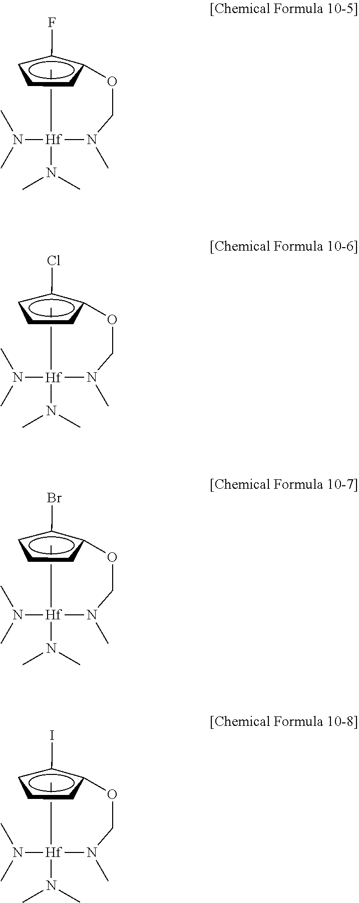

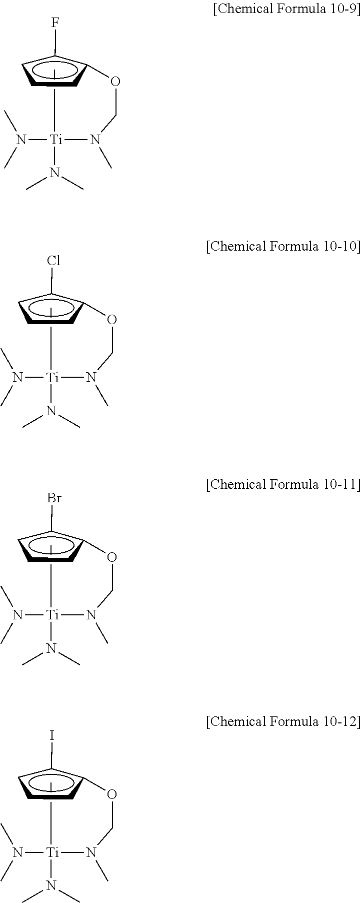

Chemical Formula 1 may be represented by any one of Chemical Formulas 11-1 to 11-12, but is not necessarily limited thereto.

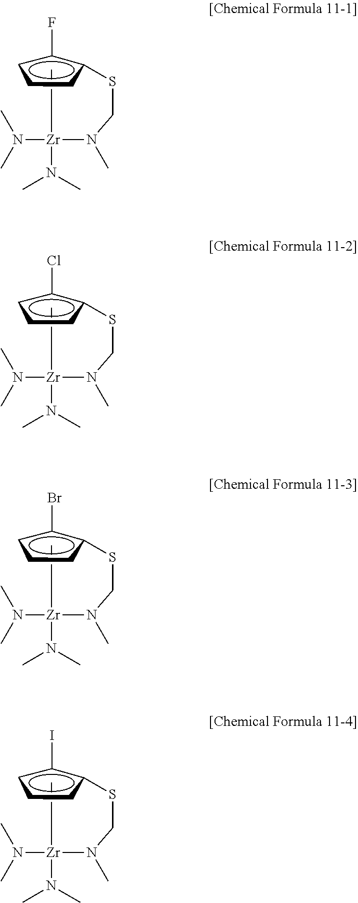

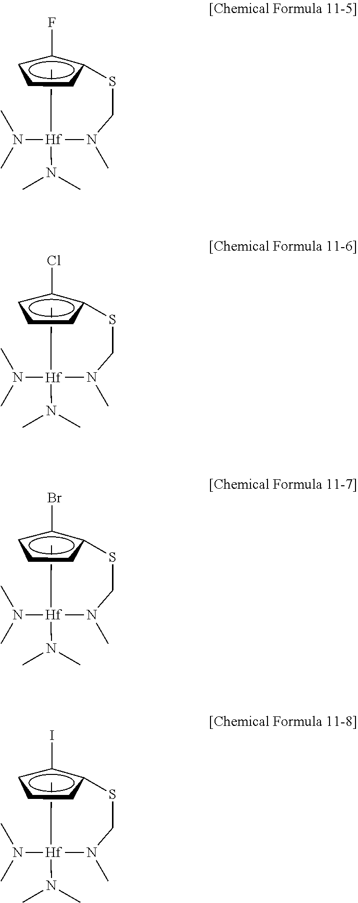

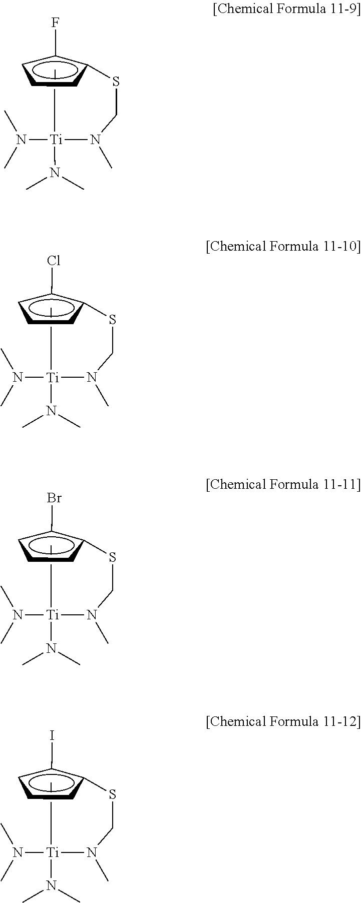

Chemical Formula 1 may be represented by any one of Chemical Formulas 12-1 to 12-12, but is not necessarily limited thereto.

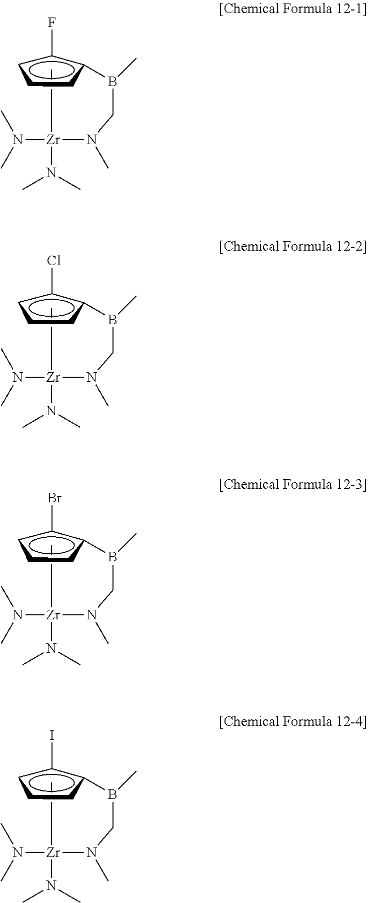

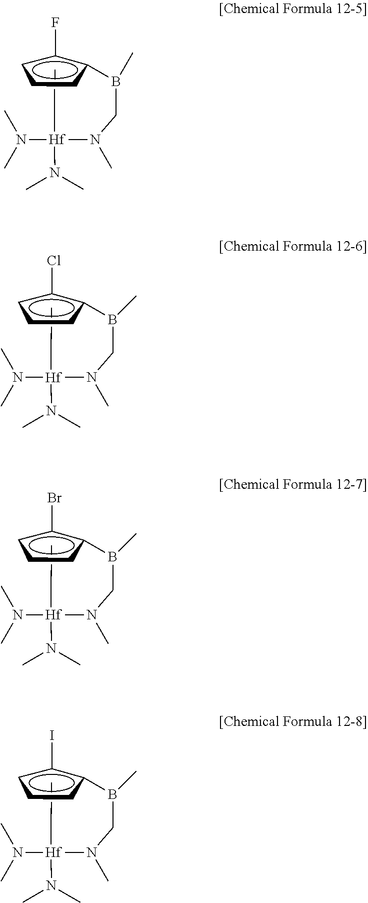

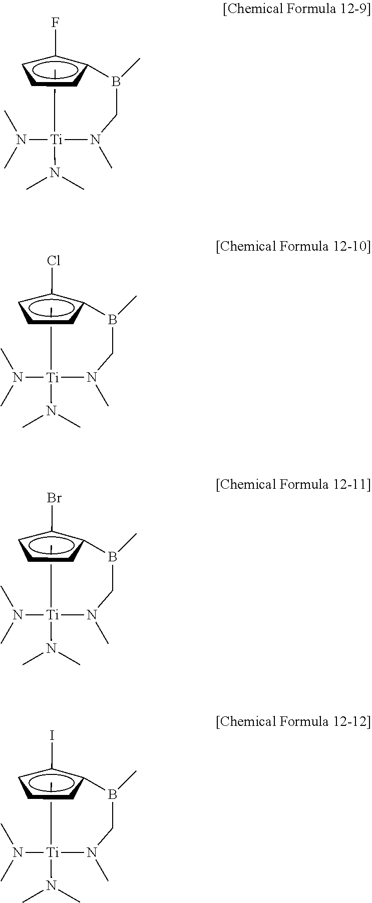

Chemical Formula 1 may be represented by any one of Chemical Formulas 13-1 to 13-12, but is not necessarily limited thereto.

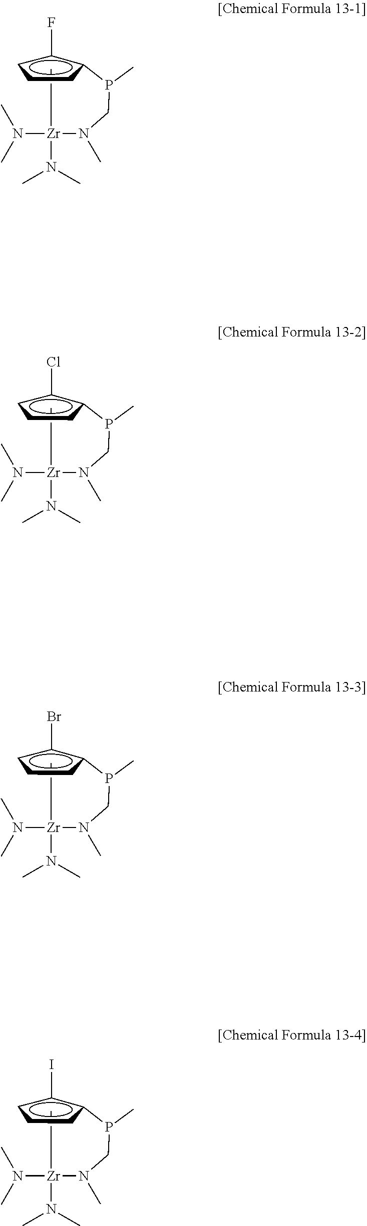

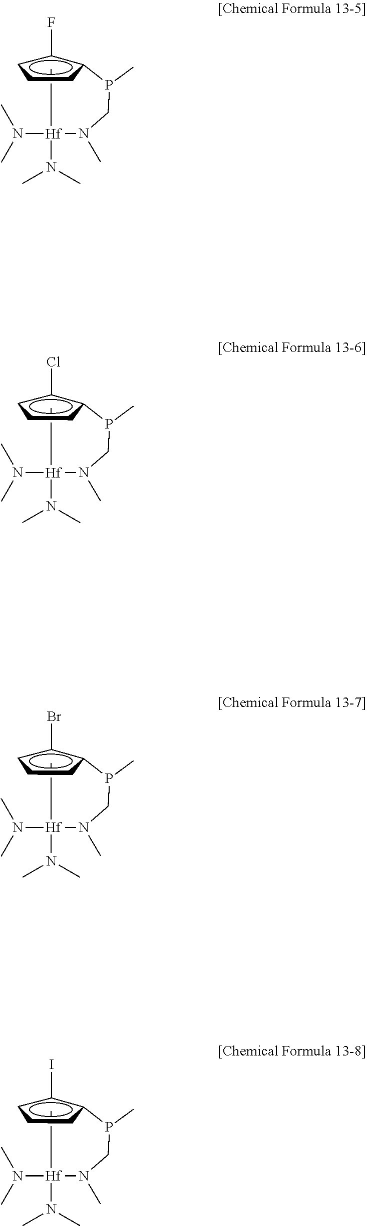

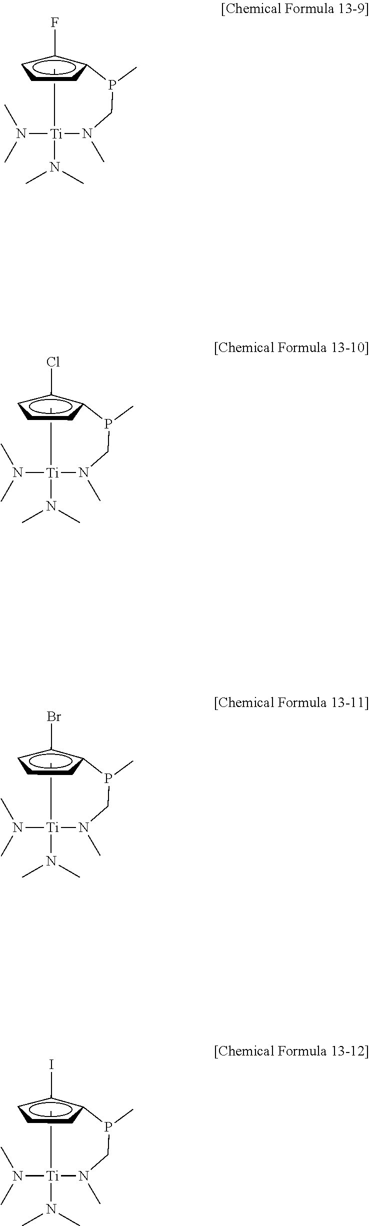

Chemical Formula 1 may be represented by any one of Chemical Formulas 14-1 to 14-12, but is not necessarily limited thereto.

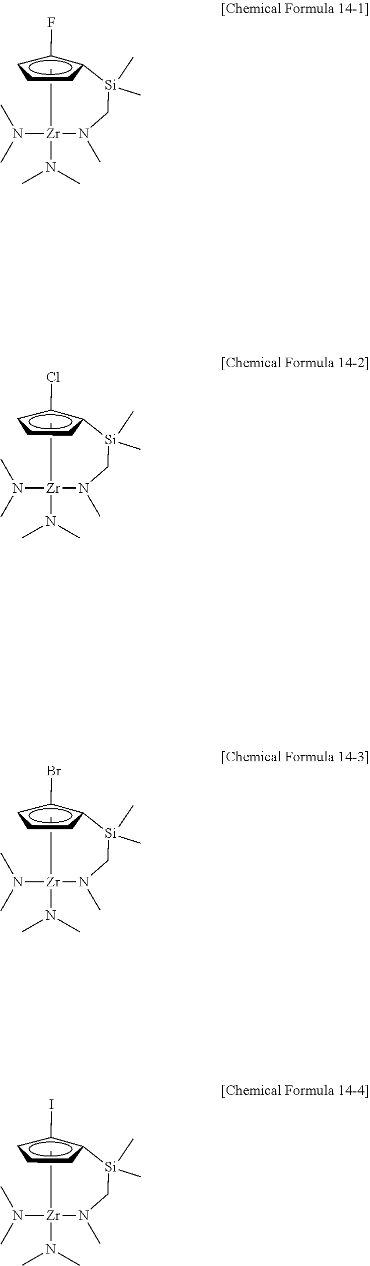

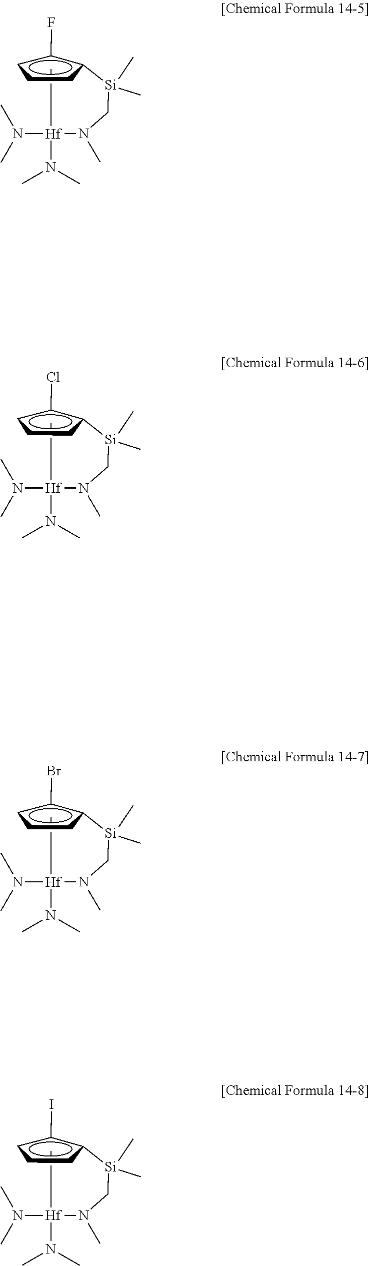

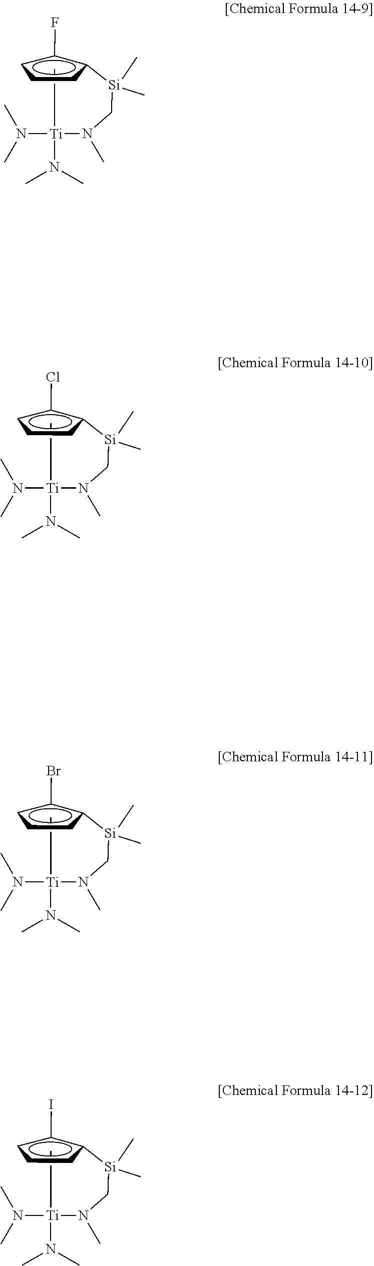

Chemical Formula 1 may be represented by any one of Chemical Formulas 15-1 to 15-12, but is not necessarily limited thereto.

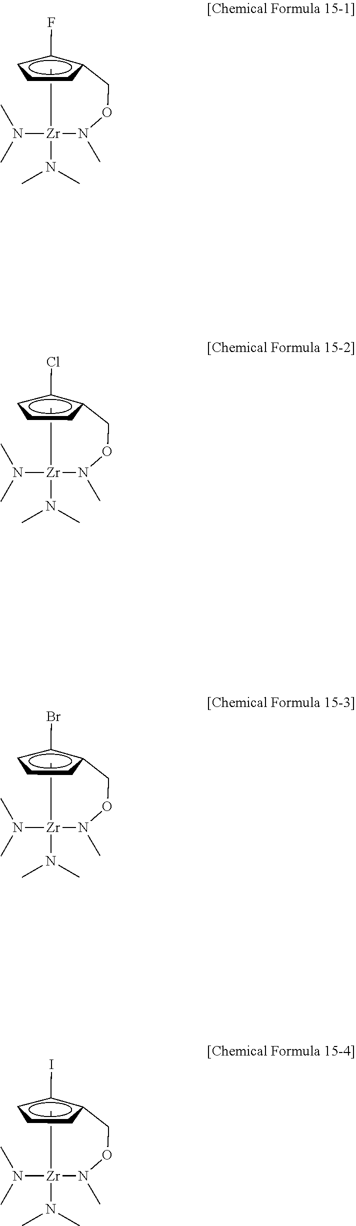

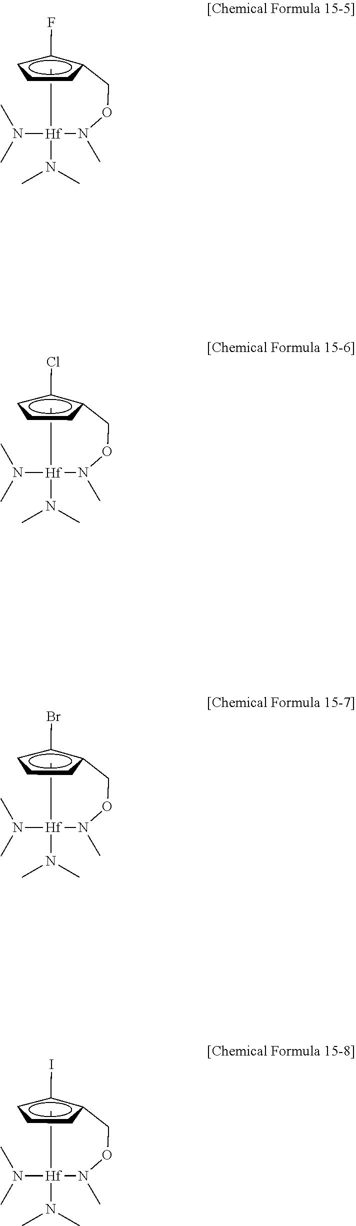

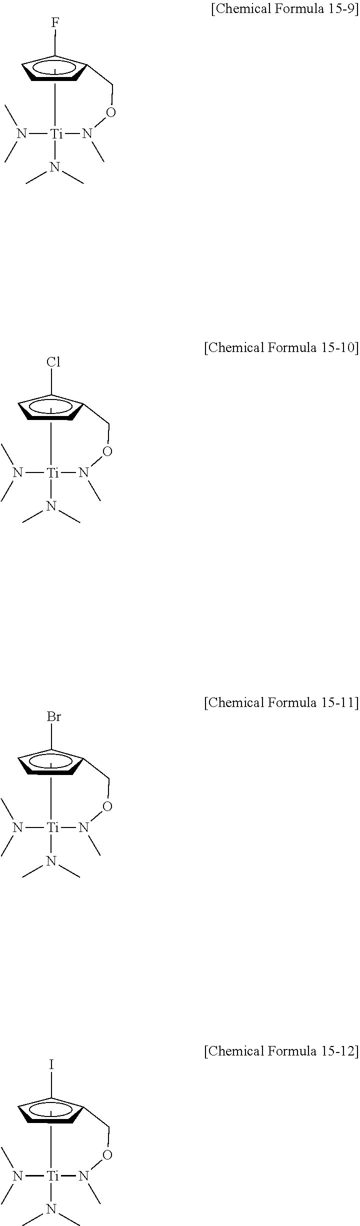

Chemical Formula 1 may be represented by any one of Chemical Formulas 16-1 to 16-12, but is not necessarily limited thereto.

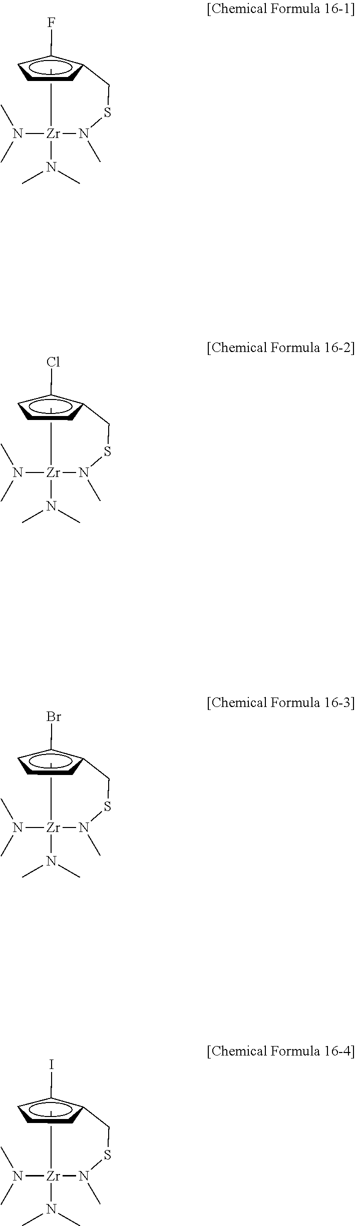

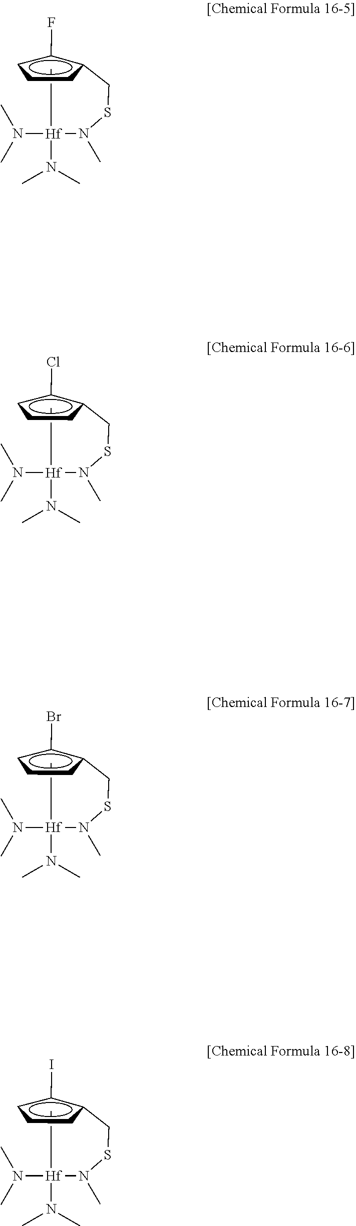

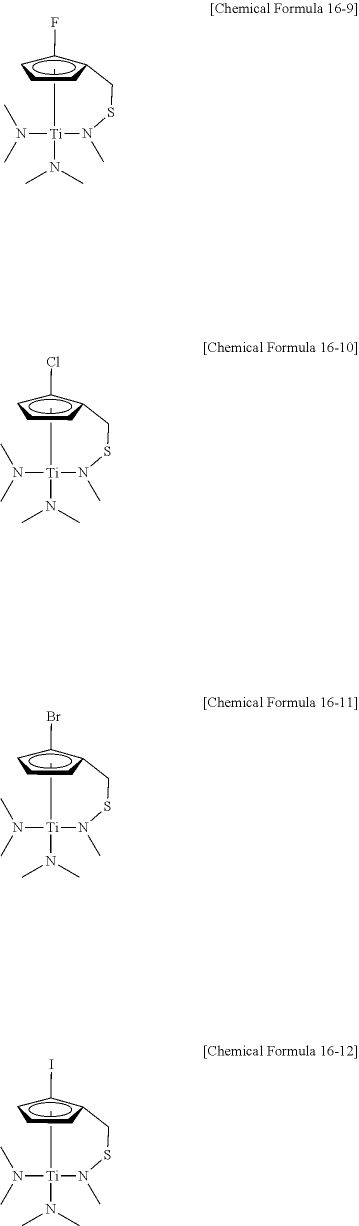

Chemical Formula 1 may be represented by any one of Chemical Formulas 17-1 17-12, but is not necessarily limited thereto.

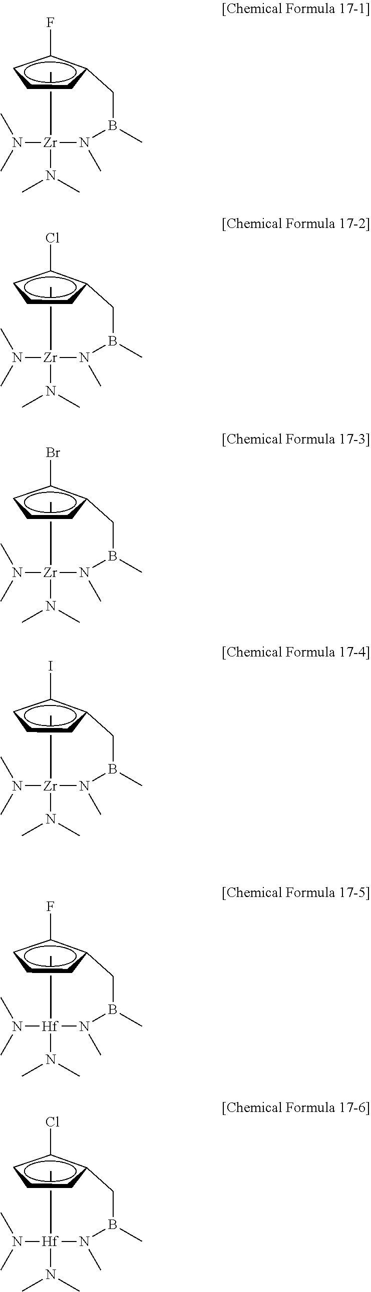

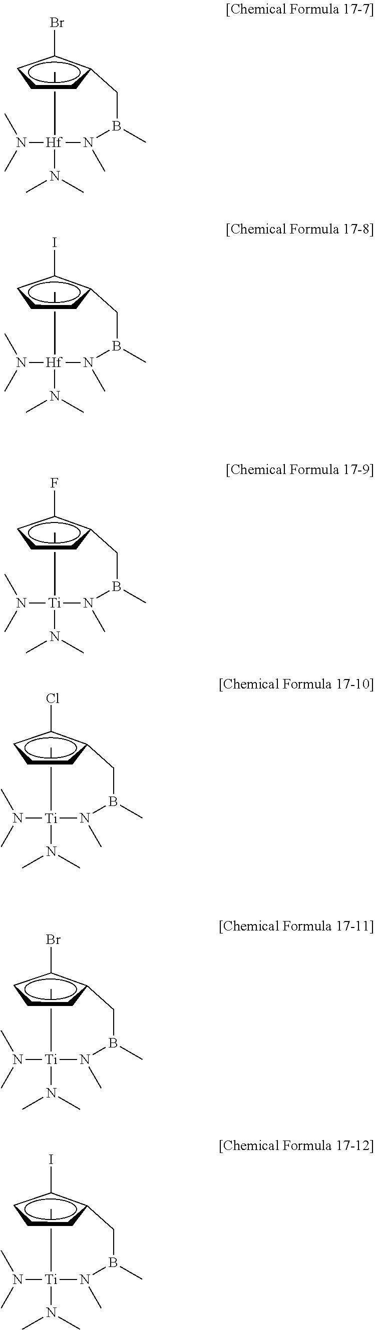

Chemical Formula 1 may be represented by any one of Chemical Formulas 18-1 to 18-12, but is not necessarily limited thereto.

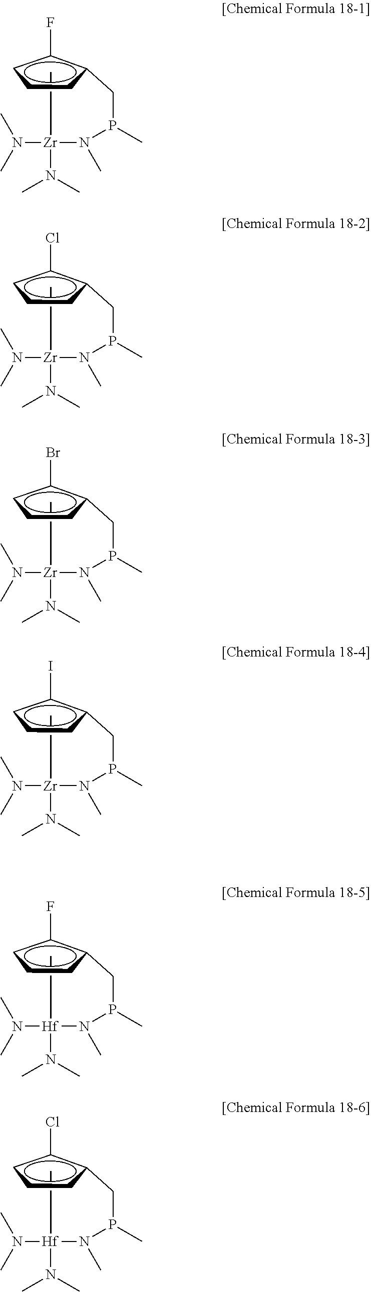

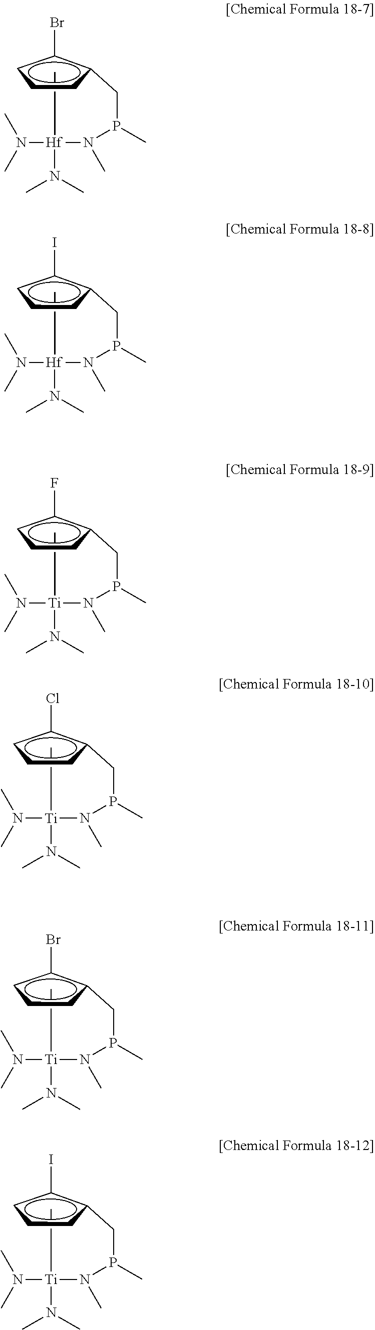

Chemical Formula 1 may be represented by any one of Chemical Formulas 19-1 to 19-12, but is not necessarily limited thereto.

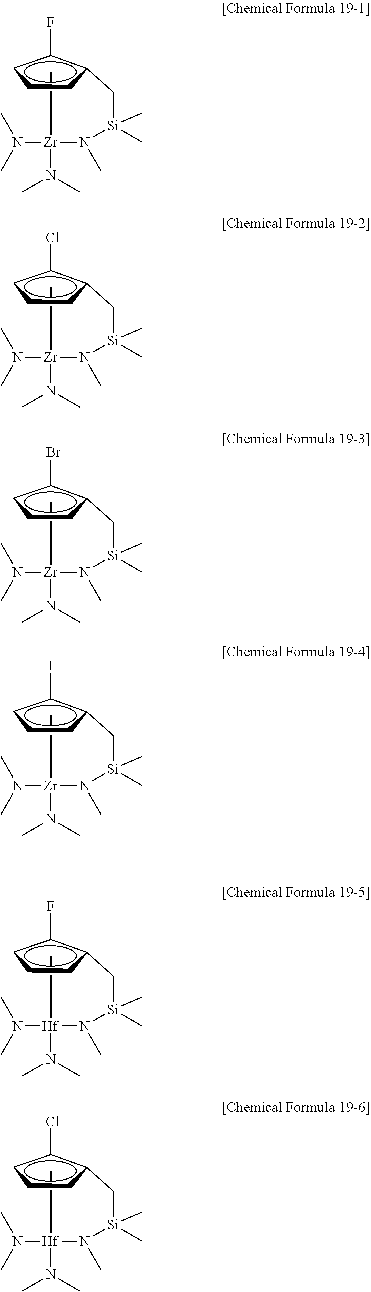

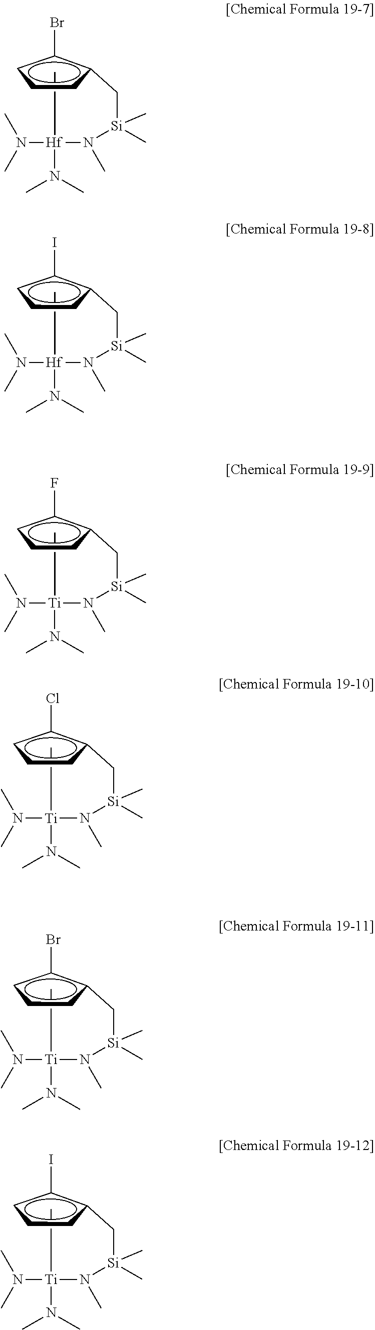

According to another embodiment, a metal oxide thin film formed by depositing the above-described metal oxide thin film precursor on a substrate is provided.

According to another embodiment, a method of forming the metal oxide thin film can be provided. Hereinafter, a method of forming the metal oxide thin film will be described in detail.

The method of forming a metal oxide thin film includes a first step of supplying the metal oxide thin film precursor onto a substrate and adsorbing the metal oxide thin film precursor onto the surface of the substrate; a second step of supplying at least one of an oxygen-containing gas, a nitrogen-containing gas, and plasma to react with the metal oxide thin film precursor to form a metal oxide thin film on the substrate; and a third step of sequentially repeating the first step and the second step.

For example, the substrate may be a silicon wafer, silicon on insulator (SOI) substrate, or titanium nitride (TiN).

To form the metal oxide thin film, the substrate may first be placed in a deposition chamber, and the metal oxide thin film precursor represented by Chemical Formula 1 may be supplied into the deposition chamber. When depositing on the substrate using the metal oxide thin film precursor according to an embodiment, the deposition temperature is desirably about 100° C. to about 1000° C. A method of transferring the metal oxide thin film precursor onto the substrate is not particularly limited but may be selected from a volatilized gas transfer method, a direct liquid injection (DLI) method, a liquid transfer method of transferring the metal oxide thin film precursor after dissolving it in an organic solvent, or the like.

The metal oxide thin film precursor may be vaporized and supplied into the chamber. The supplied metal oxide thin film precursor may be adsorbed on the surface of the substrate. And the metal oxide thin film precursor gas that is not adsorbed on the surface of the substrate is purged out. Then, oxygen-containing gas, nitrogen-containing gas, plasma, or a combination thereof is supplied into the chamber to react with the metal oxide thin film precursor adsorbed on the surface of the substrate to form a metal oxide film of one atomic thin film layer. The oxygen-containing gas may include aqueous vapor (H₂O), oxygen (O₂), ozone (O₃), hydrogen peroxide (H₂O₂), nitrous oxide (N₂O), or a combination thereof. The nitrogen-containing gas may include nitrogen (N₂), ammonia (NH₃), hydrazine (N₂H₄), nitrous oxide (N₂O), or a combination thereof. Other ligands bound to metals (e.g., zirconium) in the metal oxide thin film precursor may be combined with the oxygen-containing gas or the nitrogen-containing gas to change into gases such as carbon dioxide, aqueous vapor, and nitrogen dioxide. These by-products are purged out of the chamber. This process is repeated n times to form a metal oxide thin film of a certain thickness. Here, n corresponds to a positive integer. Through the repetition n times, a metal oxide thin film (dielectric film) with uniform atomic distribution can be formed.

For example, a conductive film may be additionally formed on the metal oxide thin film at a temperature of about 500° C. or higher. For example, the conductive film may be a tungsten film. The metal atoms may diffuse while forming the conductive film.

For example, the metal oxide thin film may correspond to a dielectric film of a capacitor, but may also correspond to a gate insulating film. The conductive film may correspond to the top electrode or gate electrode of the capacitor. When the metal oxide thin film is a capacitor metal oxide thin film, the lower electrode may be formed before forming the metal oxide thin film.

As described above, the metal oxide thin film may be formed by an atomic layer deposition (ALD) or a metal organic chemical vapor deposition (MOCVD).

Meanwhile, according to another embodiment, a semiconductor device including a thin film formed by depositing the above-described metal oxide thin film precursor or a metal oxide thin film formed by the above-described metal oxide thin film forming method may be provided.

Hereinafter, the embodiments are illustrated in more detail with reference to examples. These examples, however, are not in any sense to be interpreted as limiting the scope of the invention.

### Example 1: Synthesis of Compound Represented by Chemical Formula 2-4

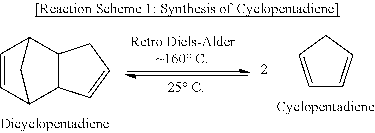 [SMILES: C1=CC2C3C=CC(C3)C2C1 ; C1=CCC=C1]

To a 250 mL 1-neck round bottom flask, 50 g (378.215 mmol) of dicyclopentadiene and a magnetic bar are added, a vigreux condenser and a liebig condenser are connected thereto, and a lab glassware connection thereof is covered with cloth and foil. Subsequently, a 100 mL 1-neck round bottom flask is connected to where a product therefrom flows over, and an ice bath (dry-ice+acetone) is installed to create a fractional distillation setting. After setting a heating mantle at 160° C., a process that the product passing through the condenser is accumulated is checked for 3 to 4 hours. When a reaction is stopped is determined, while checking an amount of the reactant, the heating mantle is turned off. When the reaction is completed, the 100 mL 1-neck round bottom flask (cyclopentadiene 31.4 g (a yield: 62.4%)) is sealed and stored in a freezer.

¹H NMR (400 MHz, Chloroform-d) b 6.61 (ddd, J=5.6, 3.0, 1.6 Hz, 2H), 6.49 (dq, J=5.4, 1.4 Hz, 2H), 3.01 (p, J=1.5 Hz, 2H).

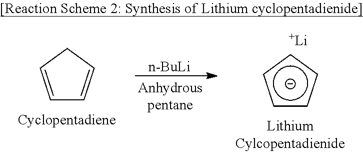

2.0 g (30.26 mmol, 1.5 eq) of the liquid cyclopentadiene is added to a 100 mL 1-neck round flask (joint size: 14/20) and then, stirred by putting g magnetic stir bar (an egg bar type, length 2 cm) therein and inserting a septum thereinto. After installing a 0° C. ice-bath, 30 mL of liquid anhydrous pentane is added to the process (putting cyclopentadiene in a flask and stirring it) and then, stirred for 30 minutes. Subsequently, 8.22 mL (20.55 mmol, 1.0 eq) of a 2.5 M n-BuLi hexane solution is dropped over 1 hour. While dropping, a clear transparent solution therein is seen to be changed into an opaque white material. When the dropping is completed, after removing the ice bath, the material is additionally stirred for 30 minutes under a room temperature (RT) condition to maintain it at room temperature. During the stirring for 30 minutes, the solution is changed into a slush state with increased viscosity. A Buchner funnel and a pressure reduction flask are used to 2 to 3 times filter it under a pressure reduction, while a small amount of anhydrous pentane is added thereto. A white powder material is obtained through the filtration (1.5 g, a yield: 68.8%).

¹H NMR (DMSO-d₆): δ 5.32 (s, 5H)

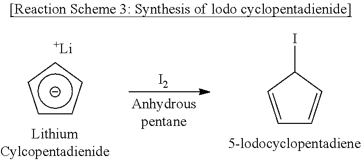

0.39 g (5.41 mmol, 1 eq) of the lithium cyclopentadienide as a light yellow solid is added to a 100 mL 1-neck round flask in a glove box. After taking the lab glassware out of the glove box and installing it onto a stirrer in a fume hood, its internal atmosphere is changed into a N₂ condition. Subsequently, 50 mL of an anhydrous pentane solvent is added thereto to check a dispersed state and then, stirred for 10 minutes. After preparing a bath with a ratio of water:methanol=3:2 (vol) and adding dry ice thereto to set the bath at −20° C., the lab glassware of the process (putting anhydrous pentane 50 ml and stirring for 10 minutes) is placed in the bath at −20° C. and stirred for 10 minutes to keep −20° C. After removing the septum therefrom, 1.13 g (4.46 mmol, 0.83 eq) of 12, a purple solid, is added thereto and closed again with the septum and sealed with a teflon tape. After the addition of 12, stirring proceeds for 12 hours. After the 12 hours, an opaque dispersed white material may be seen, and the corresponding material is once filtered by attaching a filter paper to a glass triangular funnel. Subsequently, a liquid obtained from the filtration includes I₂, which is extracted and removed. Herein, a small amount of I₂ may be located at the bottom during the extraction by using a sodium thiosulfate-supersaturated aqueous solution and then, also separated and removed. The sodium thiosulfate-supersaturated aqueous solution (D.I. water) is added to the produce, which is added to a separate funnel. The remaining product may be collected by adding an appropriate amount of pentane to the funnel. Subsequently, sufficient shaking and time are allowed to induce phase separation. During the shaking, an internal gas pressure is frequently removed to maintain safety. After the phase separation, the extraction is completed by checking a bright yellow liquid containing a solvent at the top of the extraction and then, separating and collecting it. The bright yellow liquid containing the solvent at the top of the extraction is placed in a dry ice-acetone bath at −78° C., and magnesium sulfate anhydrous powder is added thereto to remove moisture. While kept in the dry ice-acetone bath at −78° C., the liquid, whose color is changed when stored for 10 minutes or more, is filtered immediately after 10 minutes to remove the magnesium sulfate anhydrous powder. The bright yellow liquid (0.72 g, a yield: 69.3%) including the pentane solvent is stored in the dry ice-acetone bath at −78° C. for use.

¹H NMR C₆D₆: δ5.04 (s, 1H), δ5.96 (d, 2H), δ6.10 (d, 2H)

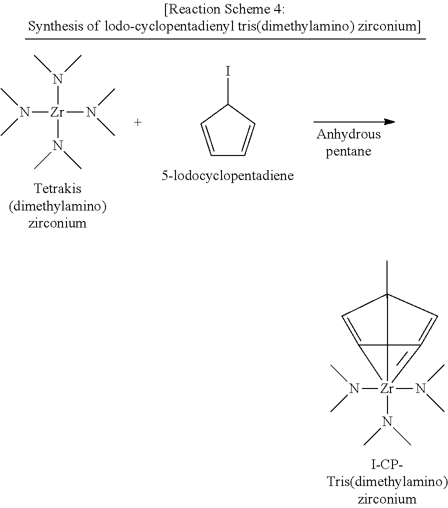

A 100 mL 3-neck round flask (joint size: 14/20), one dropping funnel, and three septums are placed in a glove box. To the 100 mL 3-neck round flask (joint size: 14/20), 1.0 g (3.74 mmol, 1 eq) of tetrakis(dimethylamino)zirconium, a yellow solid, and 15 mL of anhydrous pentane are added and then, stirred to produce a light yellow liquid, and a dropping funnel is installed onto a middle joint, and an upperjoint with the dropping funnel and the otherjoint are closed by using the septums. Gaps between all the joints are sealed by using a wax paper or a teflon tape. The lab glassware is taken out of the glove box, moved into a hood, and then, installed on a reactor. After the installation, a needle (19 gauge) is connected to the dropping funnel septum to attach a balloon of N₂ with ultra-high purity of 99.999%. When stirred for 15 to 20 minutes in a dry ice-acetone bath for −78° C., the reactant is changed into an opaque white solution. Subsequently, the 5-iodocyclopentadiene (light yellow solution) at −78° C. (in the dry ice-acetone bath) is moved to the dropping funnel by using a syringe and dropped over 1 hour, while the temperature is maintained. During the dropping over 1 hour, an opaque white color is seen. Since the corresponding experiment is very sensitive to a temperature, the −78° C. is periodically checked with a thermometer. Before the dropping is completed, a vacuum pump, a liebig condenser forvacuum distillation, and one 100 mL 1-neck round bottom flask (joint: 14/20) are prepared in advance. When the 1 hour's dropping is completed, the vacuum distillation set prepared in the process (Before the dropping is completed, a vacuum pump, a liebig condenser for vacuum distillation, and one 100 mL 1-neck round bottom flask (joint: 14/20) are prepared in advance) is immediately connected to the lab glassware as soon as the vacuum pump is turned on. (a vacuum degree of the vacuum pump: 1.0*10⁻³ Torr) after the connection, vacuum distillation is performed, while the dry ice-acetone bath is maintained at −78° C. When the solvent is removed, the vacuum pumping is completed, and the resultant is checked with NMR to obtain a compound represented by Chemical Formula 2-4 (Iodo-cyclopentadienyl tris(dimethylamino) zirconium) (0.74 g, a yield: 48.2%).

¹H NMR C₆D₆: δ6.06 (t, 2H), δ5.74 (t, 2H), δ2.84 (s, 18H)

### Comparative Example 1: Synthesis of Compound Represented by Chemical Formula C-1

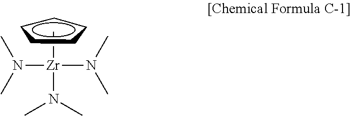

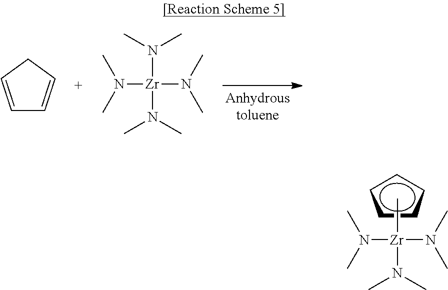

80 ml of anhydrous toluene is injected into a flame-dried 250 ml flask under a nitrogen atmosphere, and 5 g (18.7 mmol) of the tetrakis dimethylamido zirconium (IV) is added thereto and then, cooled to −78° C. After the cooling, 1.55 g (21.4 mmol) of cyclopentadiene is slowly dropped thereto by using a dropping funnel. After completing the addition, the reactant is slowly heated up to −40° C. and then stirred. When the reaction is completed, after removing solvents and volatile by-products by using vacuum, the residue is distilled under a reduced pressure (6.0 mmHg, 130° C.), obtaining 3.34 g (yield: 62%) of cyclopentadienyl tris(dimethylamino) zirconium (represented by Chemical Formula C-1), a liquid title compound.

¹H NMR C₆D₆: δ6.06 (s, 4H), 2.92 (s, 18H)

### Evaluation

### 1. Evaluation of ZrO₂ ALD Growth Behavior ((@ 300° C.)

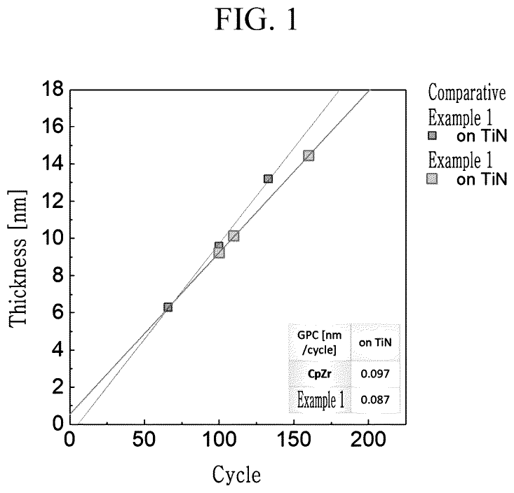

The metal oxide thin film precursors (Chemical Formulas 2-4 and C-1) according to Example 1 and Comparative Example 1 are used respectively to form metal oxide thin films (ZrO₂), and then growth behaviors of the films are evaluated, and the results are shown in FIGS. 1 to 3. Herein, TiN is used as a substrate.

Specifically, as the steps of forming the metal oxide thin films are repeated, thickness changes of the metal oxide thin films are examined, and the results are shown in FIG. 1.

Referring to FIG. 1, Example 1 and Comparative Example 1 exhibited a linear thickness growth according to an increase in cycle numbers, and in addition, Example 1 and Comparative Example 1 exhibit almost no incubation cycle (x-intercept) of less than 10 cycles, and GPC can be confirmed to be at the same level for both Example 1 and Comparative Example 1.

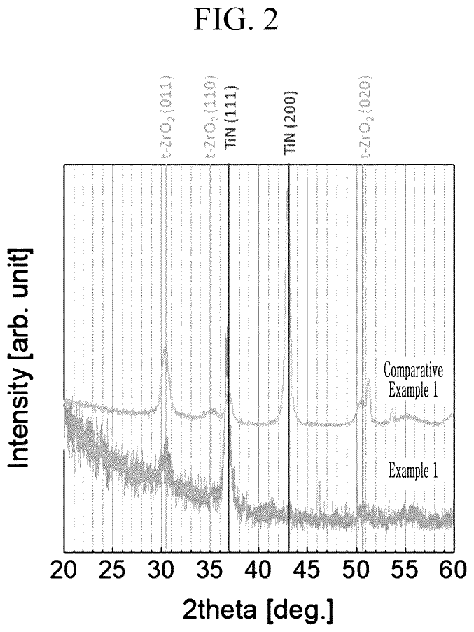

Referring to FIG. 2, at an equal deposition temperature of 300° C., the metal oxide thin film of Comparative Example 1 exhibits tetragonal crystallinity in an as-dep. state and slightly increased crystallinity after the annealing, but the metal oxide thin film of Example 1 exhibits no large difference in crystallinity between the as-dep. state and the annealing.

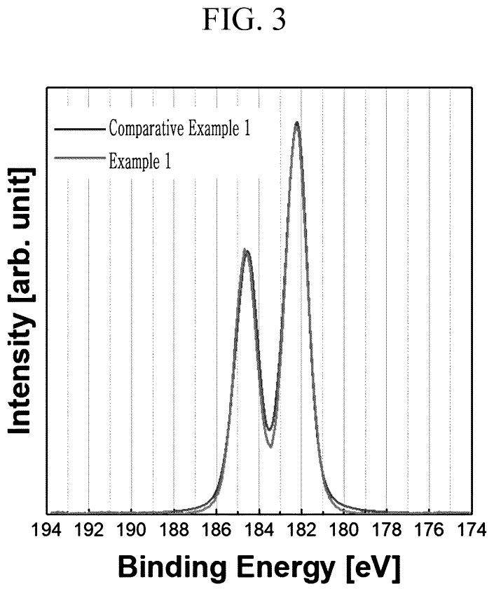

Referring to FIG. 3, both Example 1 and Comparative Example 1 exhibited an oxidation state of a Zr⁴⁺ state.

### 2. Composition Analysis of ZrO₂ Thin Film

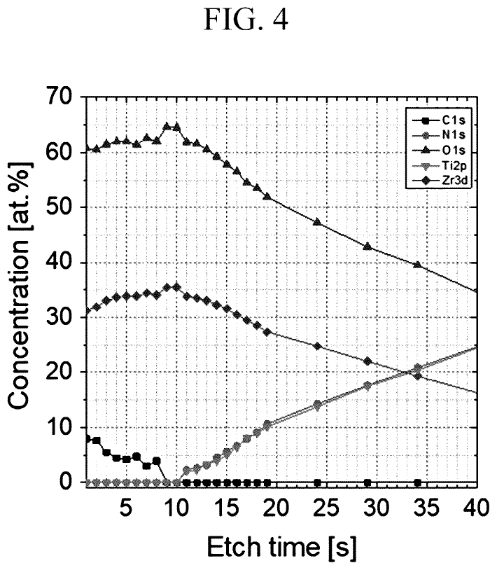

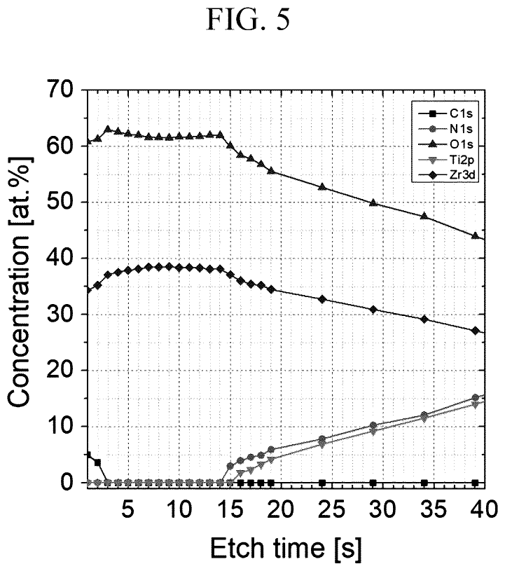

A composition analysis of the metal oxide thin films (ZrO₂) by respectively using the metal oxide thin film precursors according to Example 1 and Comparative Example 1 (Chemical Formulas 2-4 and C-1) is performed, and the results are shown in FIGS. 4 and 5 and Table 1.

TABLE 1

| Conc. [at. %] | O | Zr | O/Zr | C |
|---|---|---|---|---|
| Comparative Example 1 | 61.9 | 33.8 | 1.83 | 4.3 |
| Example1 | 62.2 | 37.8 | 1.65 | 0 |

Referring to FIGS. 4 and 5 and the Table 1, Comparative Example 1 exhibited very high residual C in the metal oxide thin film, and also stoichiometry of O/Zr=1.83, in which the film is deposited with oxygen being somewhat deficient. On the other hand, Example 1, in which residual C and N are not detected, compared with Comparative Example 1, is effectively suppressed from thermal decomposition at the deposition temperature (300° C.) due to an increase in thermal stability.

### 3. Dielectric Constant and Leakage Current in ZrO₂ Thin Film

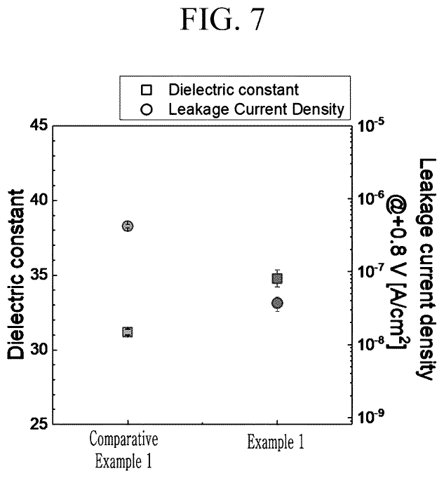

The metal oxide thin film precursors (Chemical Formulas 2-4 and C-1) according to Example 1 and Comparative Example 1 are respectively used to form each metal oxide thin film (ZrO₂), and then a dielectric constant and leakage current density thereof are measured, and the results are shown in FIG. 7 and Table 2.

TABLE 2

| | | Leakage current |
|---|---|---|
| | | density |
| | Dielectric const. | @+0.8 V [A/cm²] |
| Comparative Example 1 | 31.2 | 4.20 × 10⁻⁷ |
| Example 1 | 34.8 | 3.69 × 10⁻⁸ |

Referring to FIG. 7 and the Table 2, Example 1 exhibits a dielectric constant of 34.8, which is improved from 31.2 of that of Comparative Example 1. In other words, the dielectric constant is improved due to crystallinity improvement. In addition, Example 1 exhibits leakage current characteristics of 3.69×10⁻⁸ A/cm², which is improved from 4.20×10⁻⁷ A/cm² of that of Comparative Example 1. In other words, the leakage current characteristics are improved due to a decrease in impurities such as C and the like through improvement of thermal stability. As a result, when Example 1 is used to deposit a ZrO₂ thin film in an atomic layer deposition (ALD) method, the deposited ZrO₂ thin film exhibited improved dielectric constant characteristics and leakage current characteristics, from which performance improvement of a DRAM capacitor may be easily inferred.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

What is claimed is:

1. A metal oxide thin film precursor represented by Chemical Formula 1: 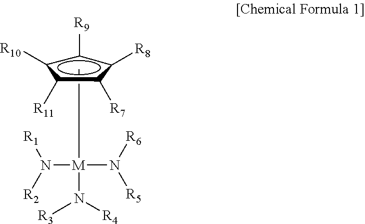
wherein, in Chemical Formula 1,
M is titanium (Ti), zirconium (Zr), or hafnium (Hf),
R¹ to R⁶ are each independently hydrogen, a halogen atom, a substituted or unsubstituted C1 to C6 alkyl group, a substituted or unsubstituted C2 to C6 alkenyl group, a substituted or unsubstituted C1 to C6 heteroalkyl group, or a substituted or unsubstituted silyl group,
R⁷ to R¹¹ are each independently hydrogen, a halogen atom, a substituted or unsubstituted C1 to C6 alkyl group, a substituted or unsubstituted C2 to C6 alkenyl group, a substituted or unsubstituted C1 to C6 heteroalkyl group, or a substituted or unsubstituted silyl group,
provided that, at least one of R¹ to R¹¹ necessarily includes a halogen atom,
at least one of R¹ to R⁶ is linked to at least one of R⁷ to R¹¹ to form a fused ring,
R¹ and R² are linked to each other to form a fused ring,
R³ and R⁴ are linked to each other to form a fused ring,
R⁵ and R⁶ are linked to each other to form a fused ring,
at least one of R¹ and R² and at least one of R³ and R⁴ are linked to each other to form a fused ring,
at least one of R³ and R⁴ and at least one of R⁵ and R⁶ are linked to each other to form a fused ring, and
at least one of R¹ and R² and at least one of R⁵ and R⁶ are linked to each other to form a fused ring.

2. The metal oxide thin film precursor of claim 1, wherein
R¹ to R⁶ are each independently a substituted or unsubstituted C1 to C6 alkyl group, a substituted or unsubstituted C1 to C6 heteroalkyl group, or a substituted or unsubstituted silyl group.

3. The metal oxide thin film precursor of claim 1, wherein
at least one of R⁷ to R¹¹ is necessarily a halogen atom.

4. The metal oxide thin film precursor of claim 3, wherein
any one of R⁷ to R¹¹ is a halogen atom, and all others are hydrogen.

5. The metal oxide thin film precursor of claim 3, wherein
any one of R⁷ to R¹¹ is a halogen atom, and the others are a substituted or unsubstituted C1 to C6 alkyl group, a substituted or unsubstituted C1 to C6 heteroalkyl group, or a substituted or unsubstituted silyl group.

6. The metal oxide thin film precursor of claim 1, wherein
at least two of R⁷ to R¹¹ are necessarily halogen atoms.

7. The metal oxide thin film precursor of claim 1, wherein
all of R⁷ to R¹¹ are halogen atoms.

8. The metal oxide thin film precursor of claim 1, wherein
R⁶ and R⁸ are linked to each other to form a fused ring.

9. The metal oxide thin film precursor of claim 8, wherein
R³ and R⁴ are linked to each other to form a fused ring.

10. The metal oxide thin film precursor of claim 8, wherein
R⁴ and R⁵ are linked to each other to form a fused ring.

11. The metal oxide thin film precursor of claim 1, wherein
Chemical Formula 1 is represented by any one of Chemical Formula 2-1 to Chemical Formula 19-12:

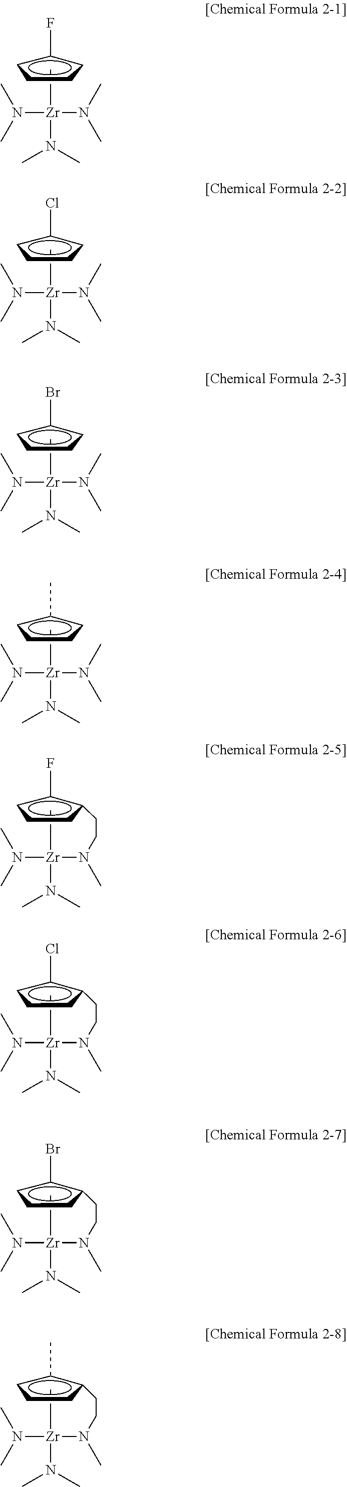

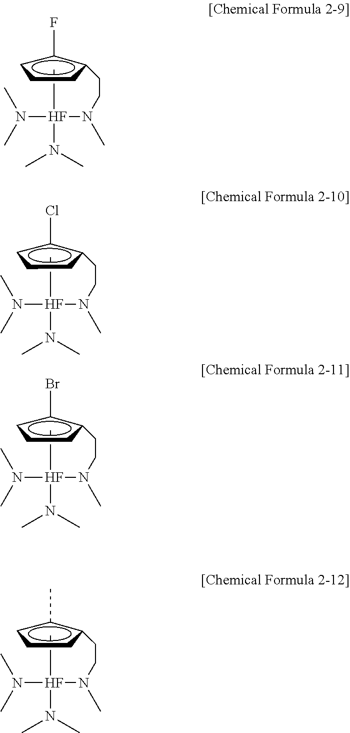

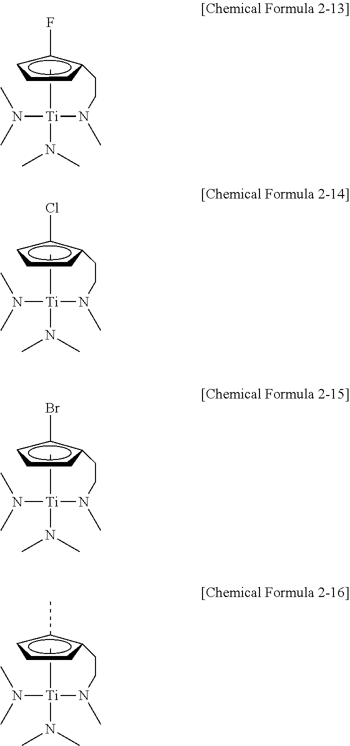

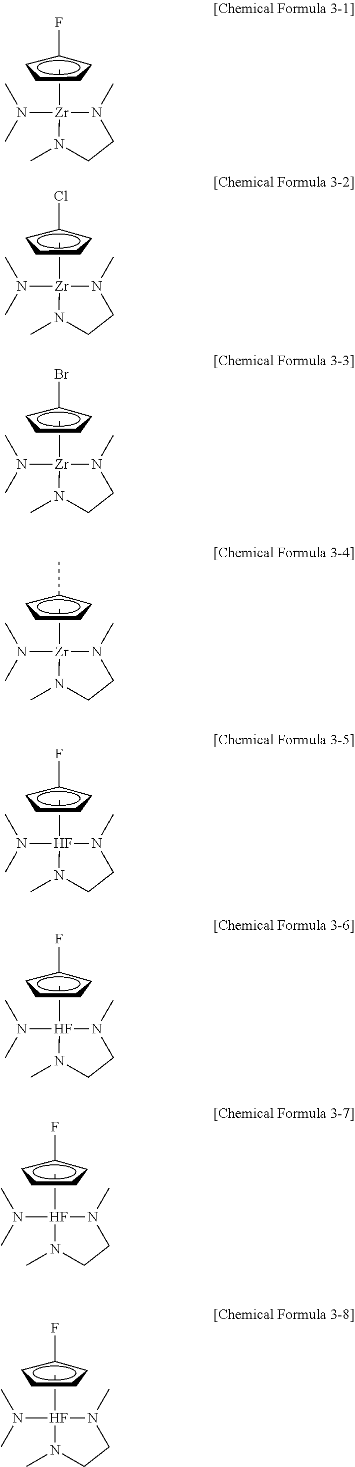

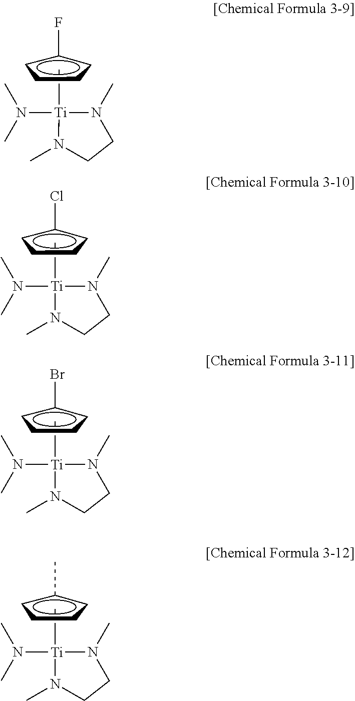

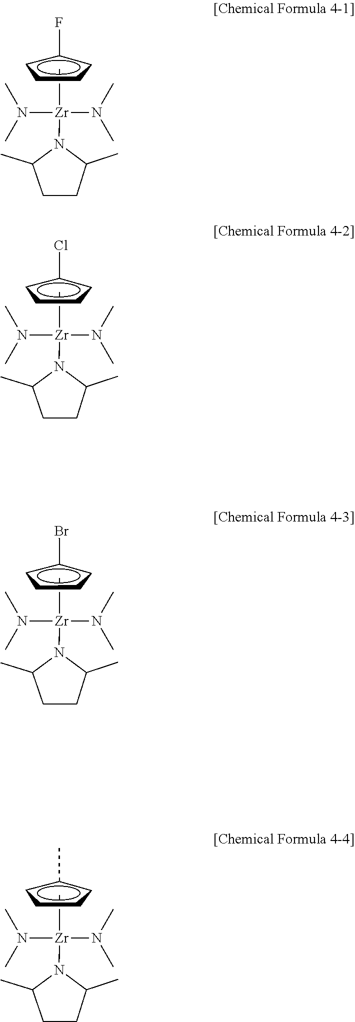

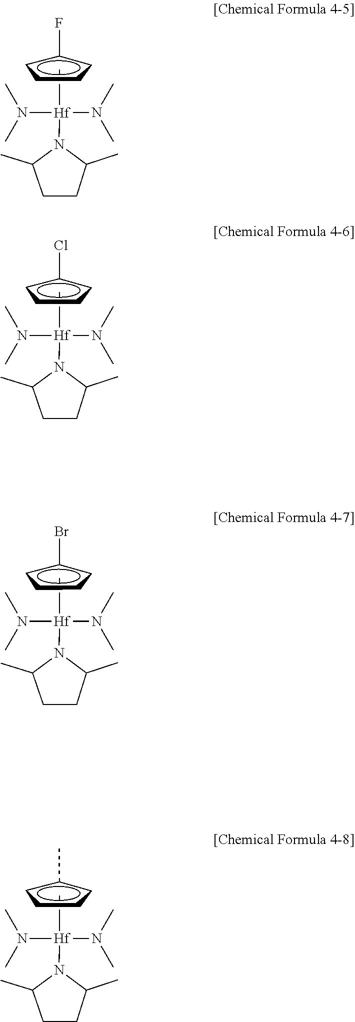

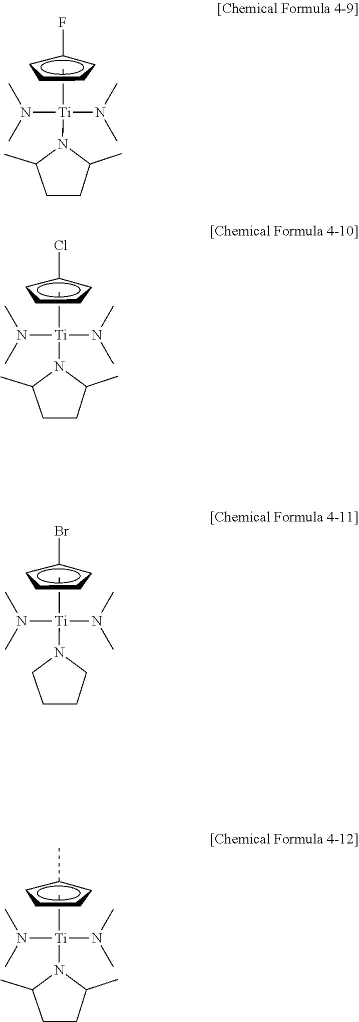

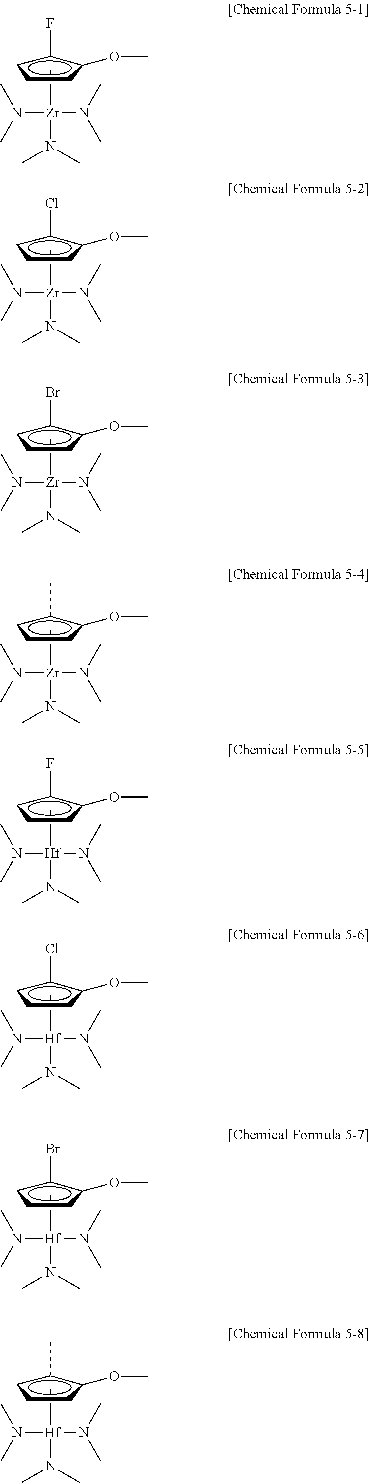

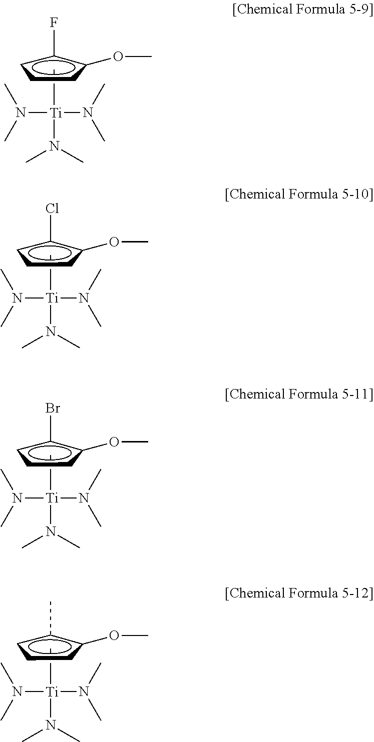

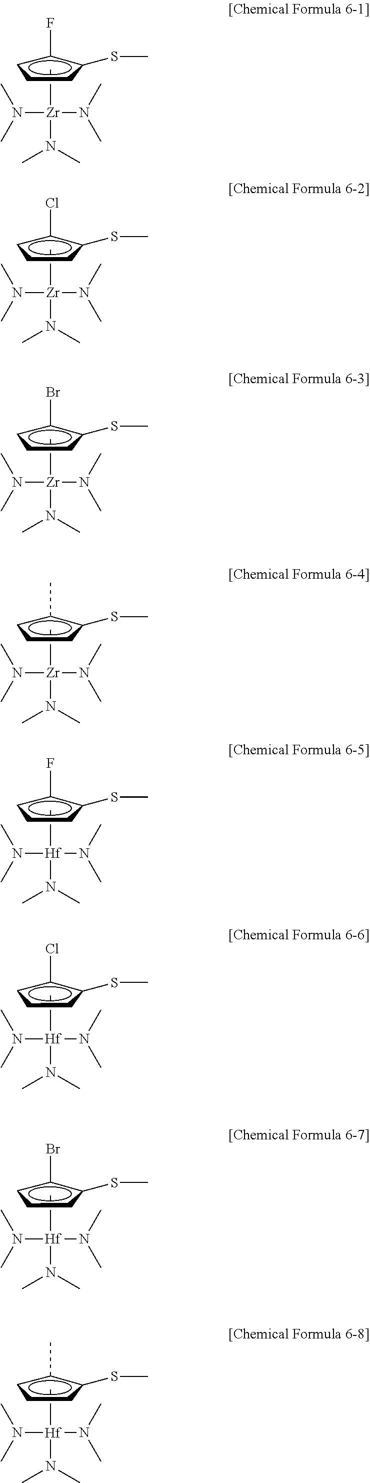

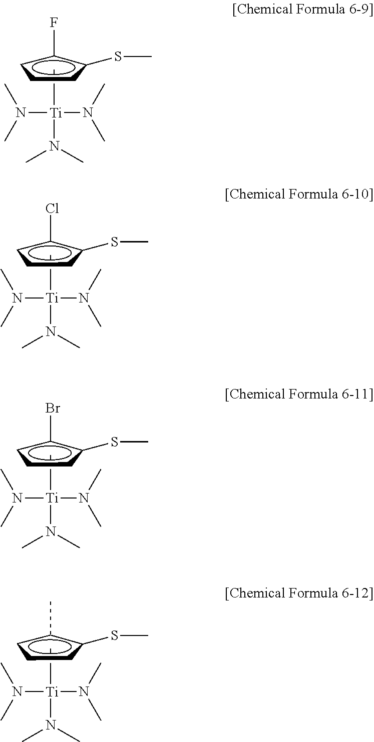

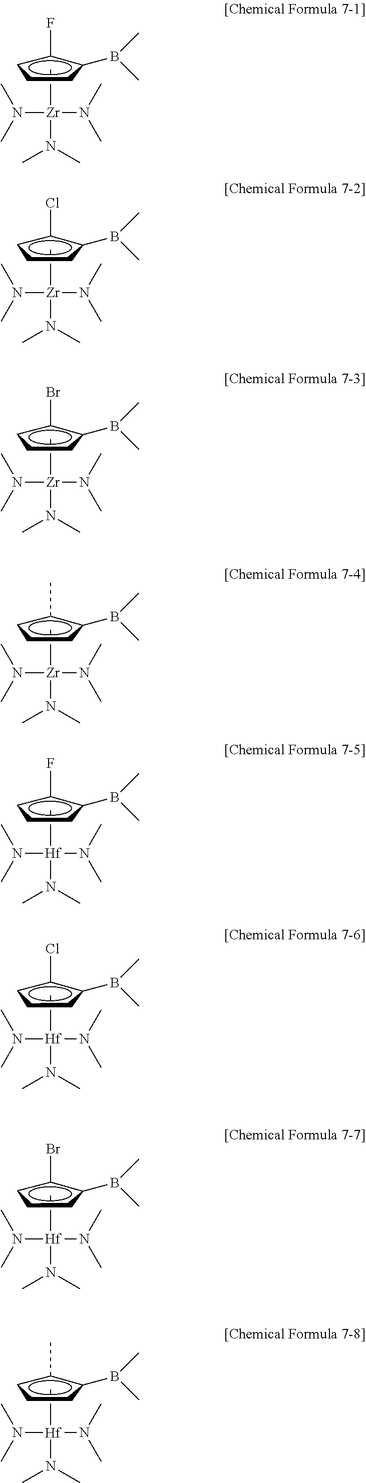

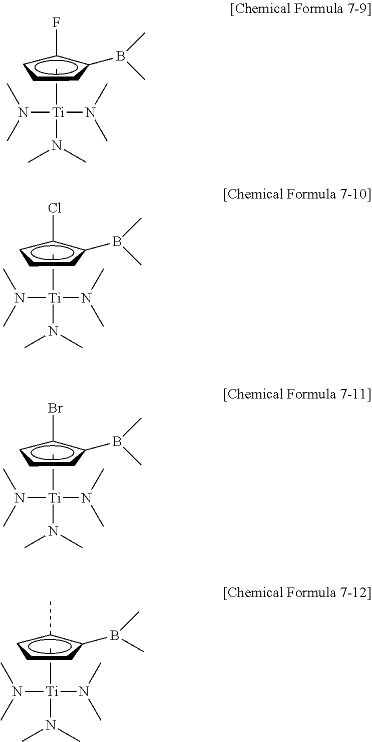

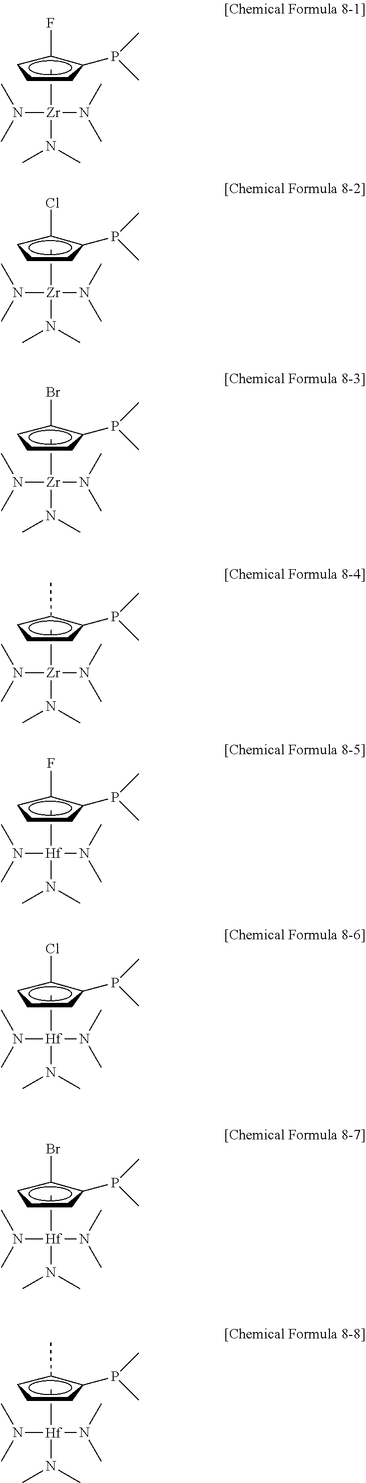

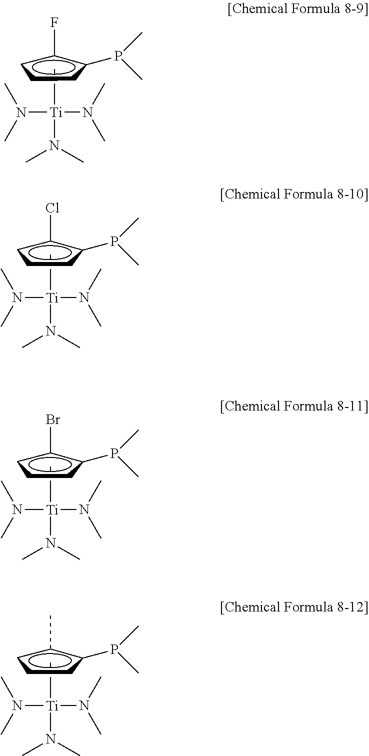

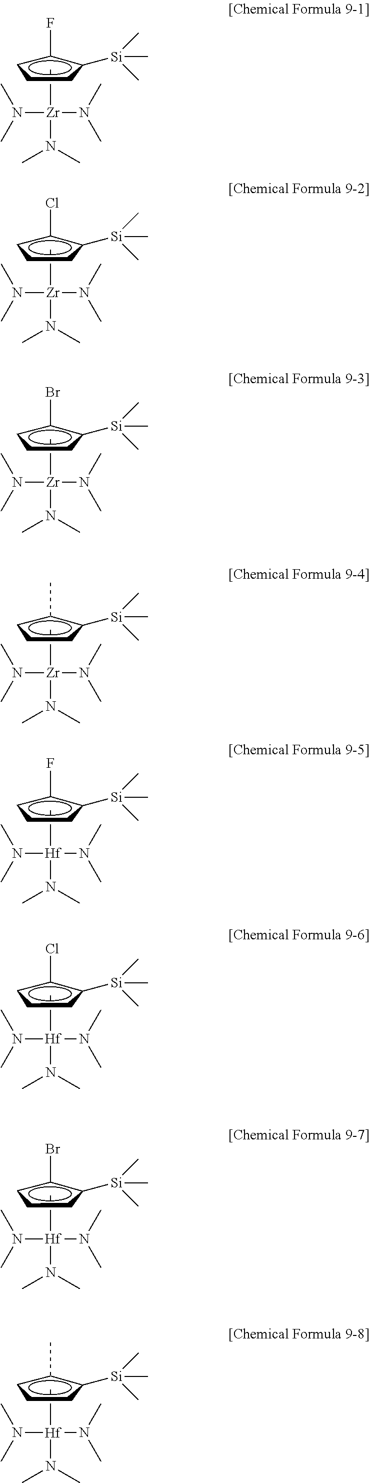

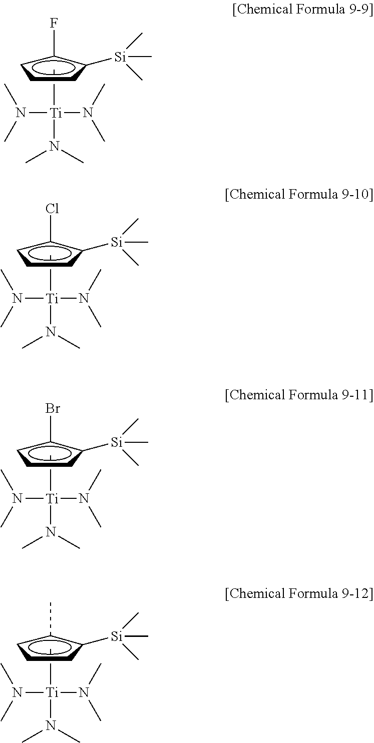

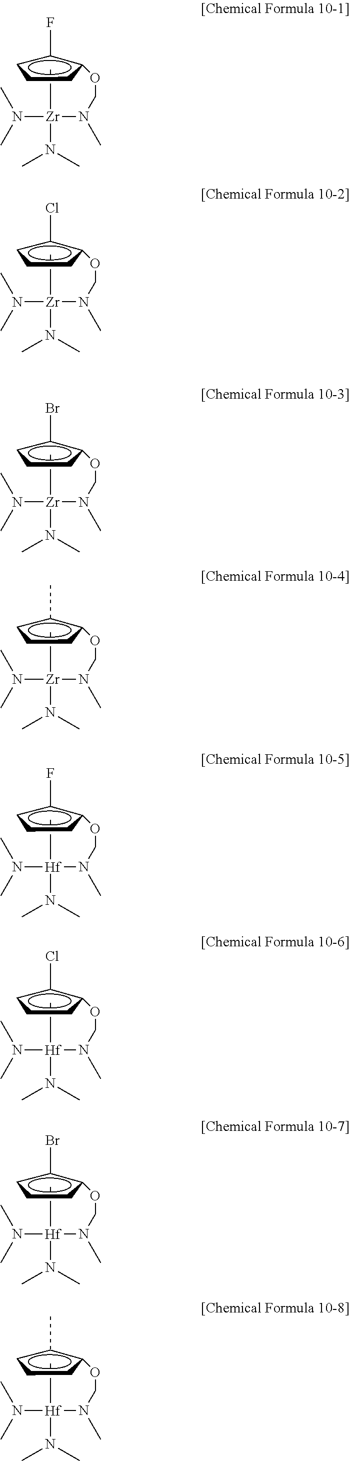

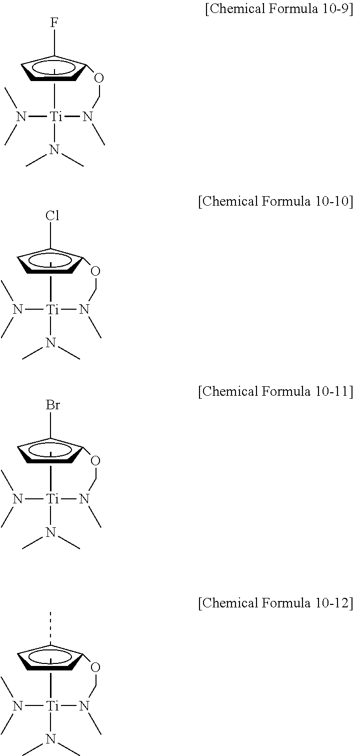

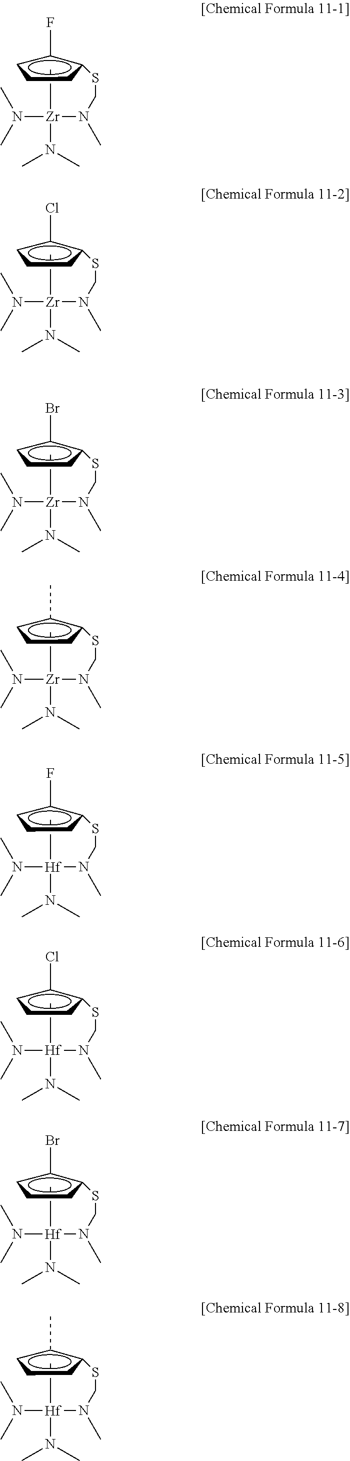

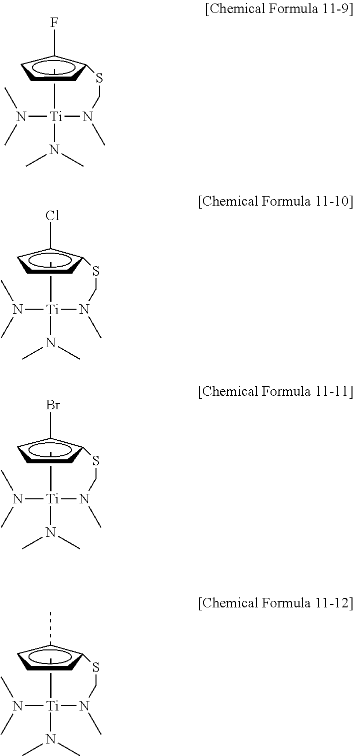

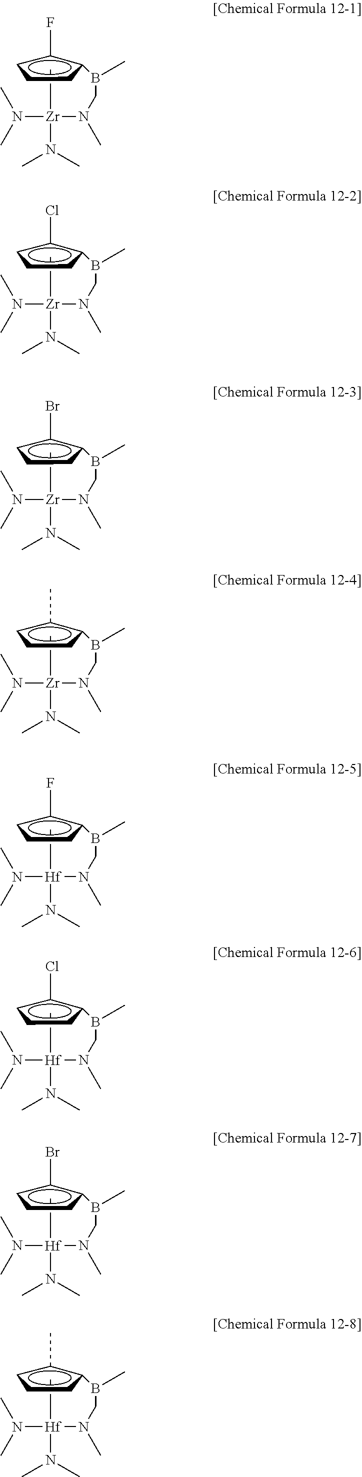

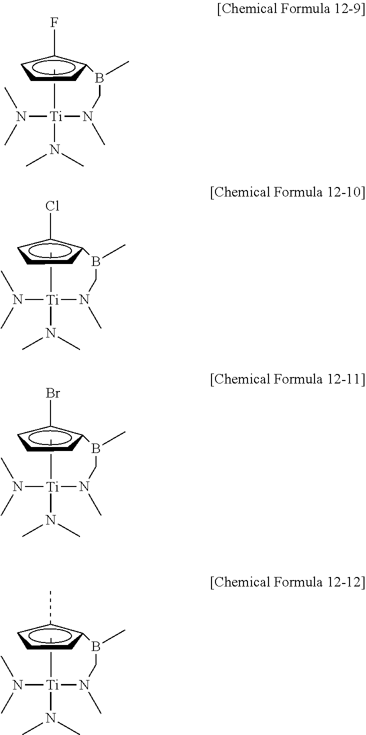

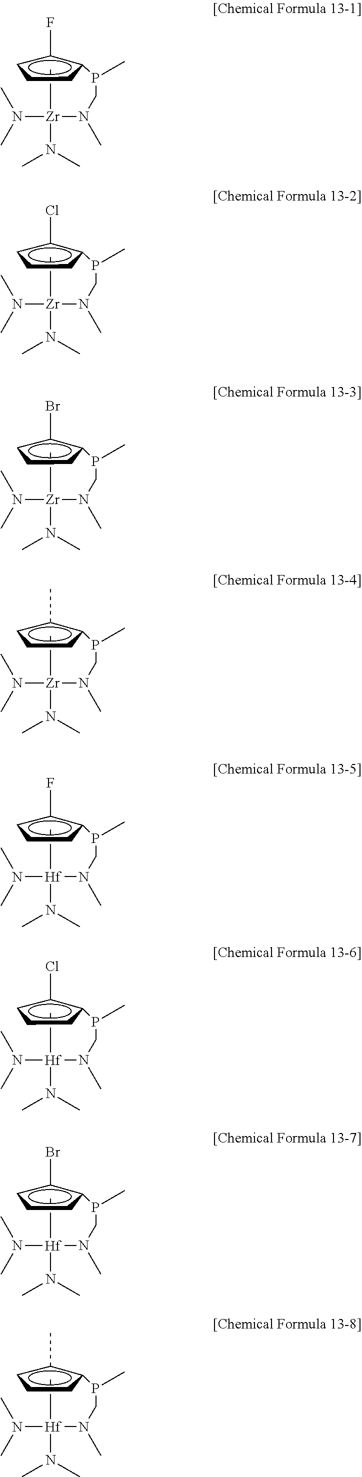

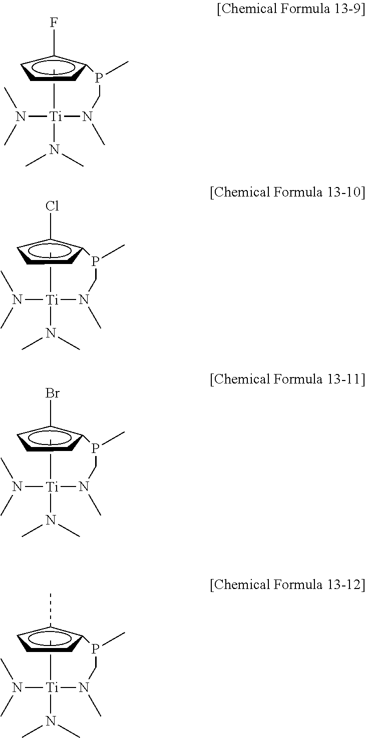

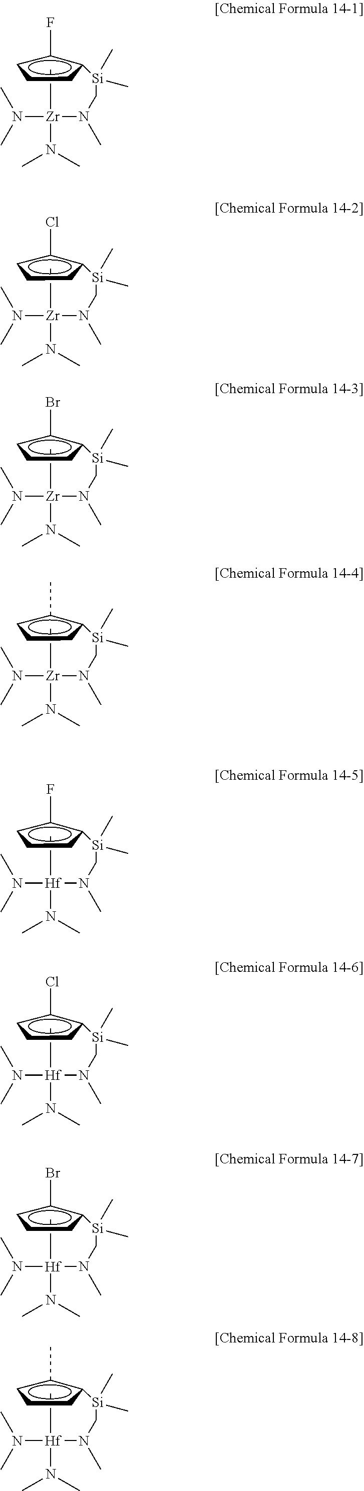

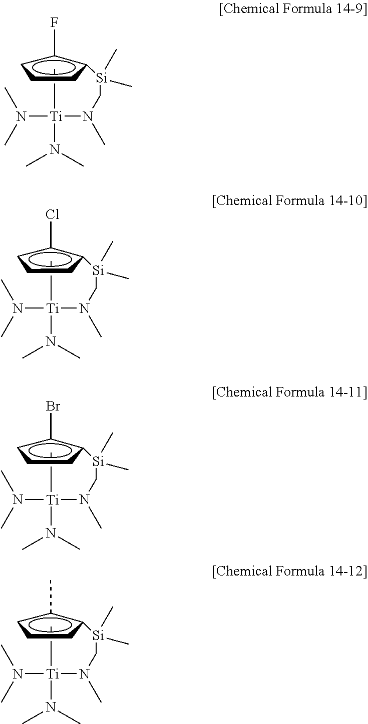

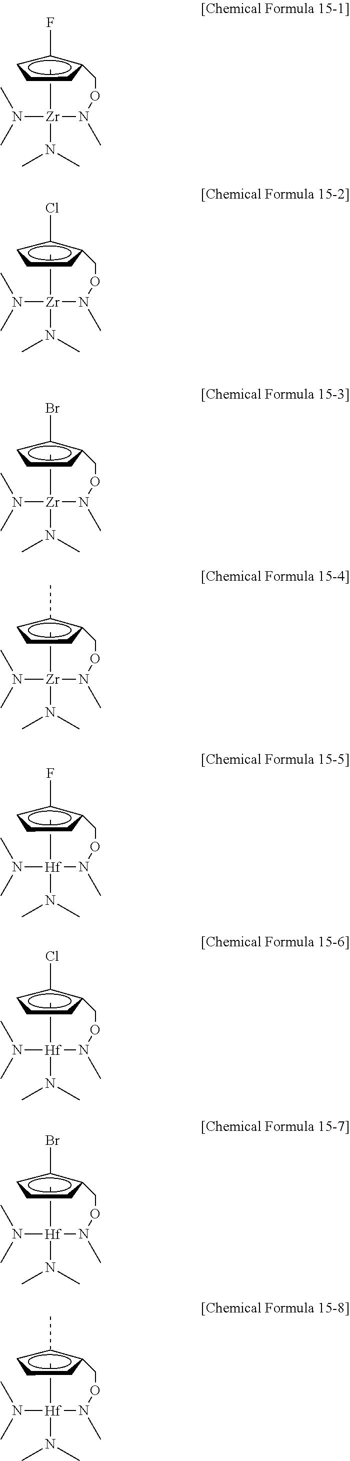

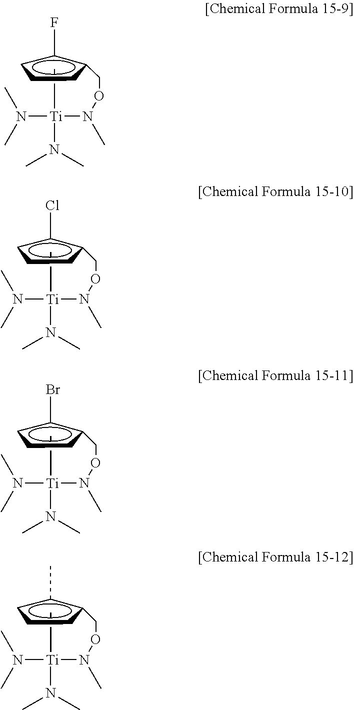

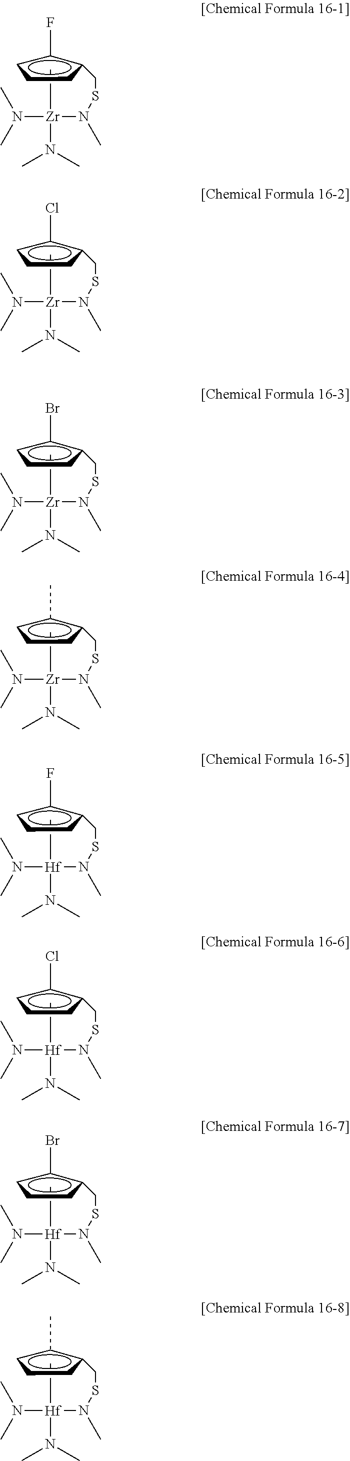

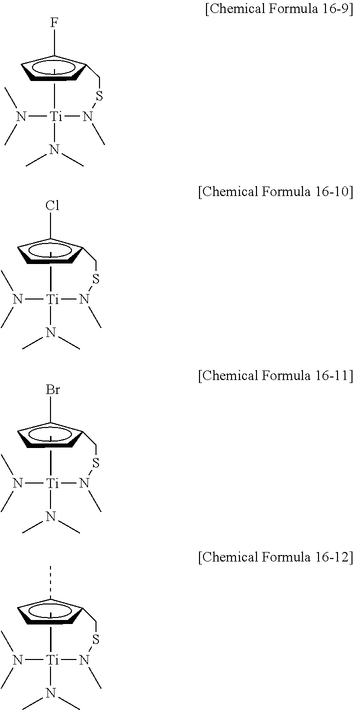

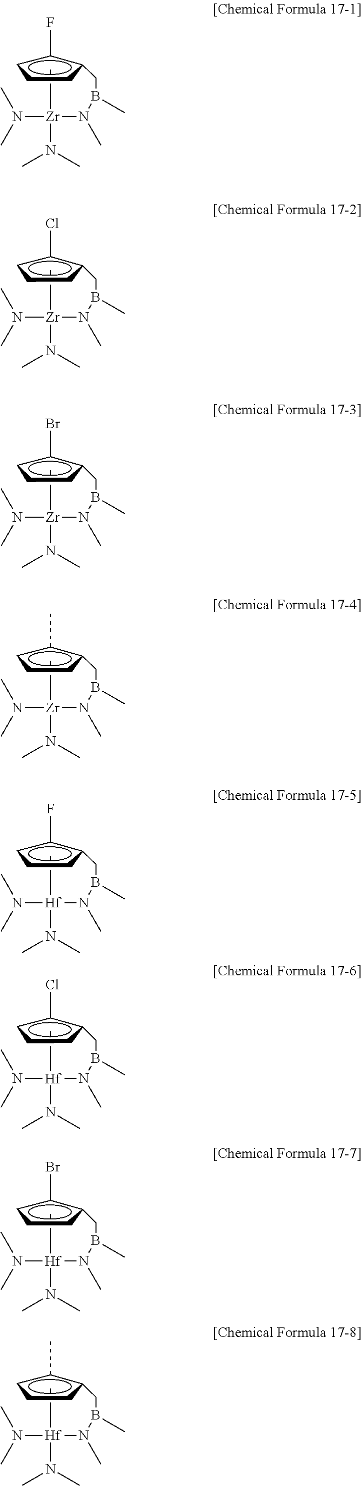

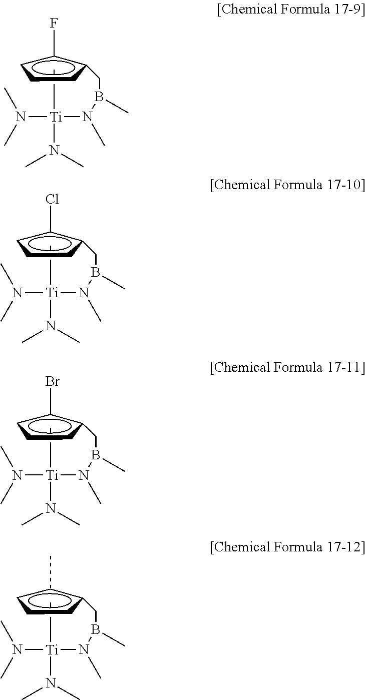

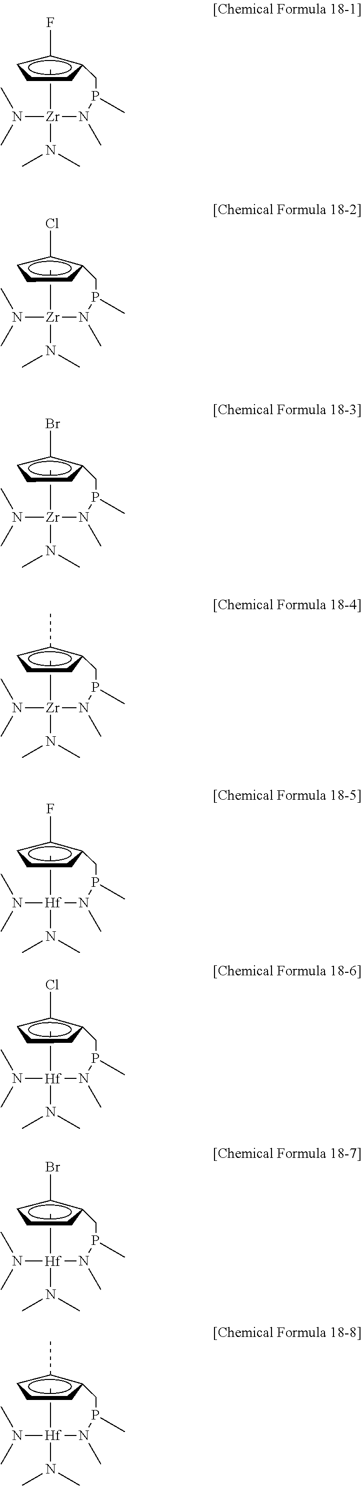

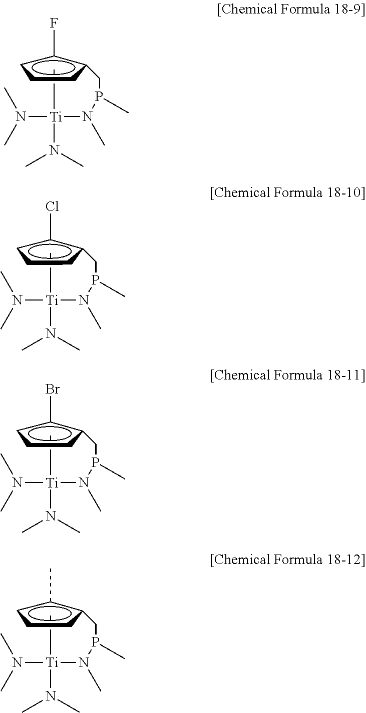

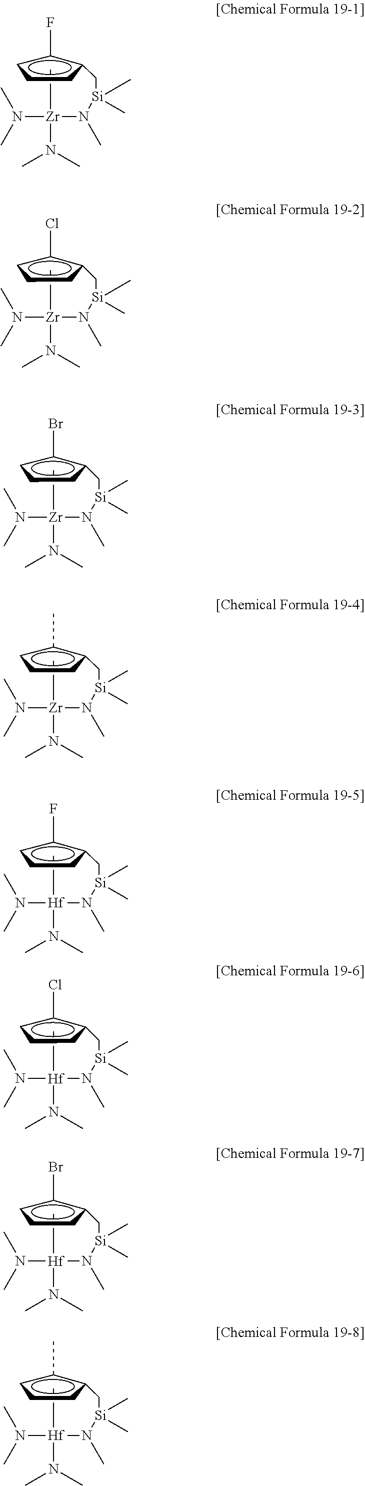

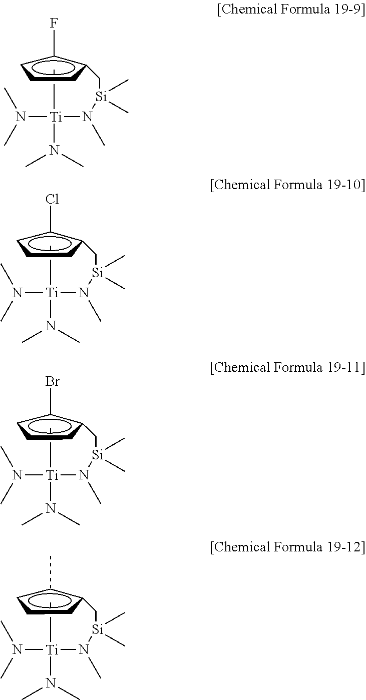

12. A method of forming a metal oxide thin film, comprising
a first process of supplying the metal oxide thin film precursor of claim 1 to a substrate to adsorb the metal oxide thin film precursor on a surface of the substrate;
a second process of supplying at least one of an oxygen-containing gas, a nitrogen-containing gas, and a plasma to react with the metal oxide thin film precursor to form a metal oxide thin film on the substrate; and
sequentially repeating the first and second processes.

13. The method of claim 12, wherein
the oxygen-containing gas includes aqueous vapor (H₂O), oxygen (O₂), ozone (O₃), hydrogen peroxide (H₂O₂), nitrous oxide (N₂O), or a combination thereof.

14. The method of claim 12, wherein
the nitrogen-containing gas includes nitrogen (N₂), ammonia (NH₃), hydrazine (N₂H₄), nitrous oxide (N₂O), or a combination thereof.

15. The method of claim 12, wherein
the method includes an atomic layer deposition (ALD) method or a metal organic chemical vapor deposition (MOCVD) method.

16. A semiconductor device comprising the metal oxide thin film of claim 12.
